(19) United States
(12) Patent Application Publication
(10) Pub. No.: US 2025/0076383 A1
(43) Pub. Date: Mar. 6, 2025

(54) METHOD OF DETERMINING STATE OF THREE-PHASE MOTOR AND ELECTRONIC DEVICE FOR PERFORMING THE METHOD

(71) Applicant: Samsung Electronics Co., Ltd., Suwon-si (KR)

(72) Inventor: Jihye PARK, Suwon-si (KR)

(21) Appl. No.: 18/804,756

(22) Filed: Aug. 14, 2024

Related U.S. Application Data
(63) Continuation of application No. PCT/KR2024/009200, filed on Jul. 1, 2024.

(30) Foreign Application Priority Data
Sep. 1, 2023 (KR) 0-2023-0116180
Oct. 23, 2023 (KR) 10-2023-0142026

(51) Int. Cl. G01R 31/34; A61H 3/00

(52) U.S. Cl. CPC G01R 31/343; G01R 31/346; A61H 3/00

(57) ABSTRACT

In a walking assist apparatus or other suitable apparatus, a method of determining a state of a three-phase motor may include applying a control voltage to an input terminal of a diagnostic circuit electrically connected to terminals of the three-phase motor, measuring a diagnostic voltage appearing at an output terminal of the diagnostic circuit, and determining whether coils of the three-phase motor are normal based on the diagnostic voltage.

### CROSS-REFERENCE TO RELATED APPLICATIONS

This application is a continuation application of International Application No. PCT/KR2024/009200 designating the United States, filed on Jul. 1, 2024, in the Korean Intellectual Property Receiving Office and claiming priority to Korean Patent Application No. 10-2023-0116180, filed on Sep. 1, 2023, and Korean Patent Application No. 10-2023-0142026, filed on Oct. 23, 2023, in the Korean Intellectual Property Office, the disclosures of which are all hereby incorporated by reference herein in their entireties.

### BACKGROUND

### 1. Field

This application relates to a technique for determining the state of a three-phase motor.

### 2. Description of Related Art

A change into aging societies has contributed to a growing number of people who experience inconvenience and pain from reduced muscular strength or joint problems due to aging. Thus, there is a growing interest in walking assist devices that enable elderly users or patients/persons with reduced muscular strength or joint problems to walk with less effort and/or to exercise.

Other features and aspects will become apparent from the following detailed description, drawings, and claims.

### SUMMARY

According to an example embodiment, a method of determining a state of a three-phase motor may include applying a control voltage to an input terminal of a diagnostic circuit electrically connected, directly or indirectly, to terminals of the three-phase motor, measuring a diagnostic voltage appearing at an output terminal of the diagnostic circuit, and determining whether coils of the three-phase motor are normal based on the diagnostic voltage.

According to an example embodiment, a diagnostic module for determining whether coils of a three-phase motor are normal may include a processor, and a diagnostic circuit, wherein the processor may perform applying a control voltage to an input terminal of the diagnostic circuit electrically connected, directly or indirectly, to terminals of the three-phase motor, measuring a diagnostic voltage appearing at an output terminal of the diagnostic circuit, and determining whether coils of the three-phase motor are normal based on the diagnostic voltage.

According to an example embodiment, a method of determining a state of a three-phase motor may include measuring an operating voltage appearing at an output terminal of a diagnostic circuit electrically connected, directly or indirectly, to terminals of the three-phase motor while the three-phase motor is controlled by a motor driver circuit based on pulse width modulation (PWM), terminating applying a driving voltage to the three-phase motor when the operating voltage is abnormal, applying a control voltage to an input terminal of the diagnostic circuit, measuring a diagnostic voltage appearing at the output terminal of the diagnostic circuit, and determining whether coils of the three-phase motor are normal based on the diagnostic voltage.

Other features and aspects will be apparent from the following detailed description, drawings, and claims.

### BRIEF DESCRIPTION OF THE DRAWINGS

The above and other aspects, features, and advantages of certain example embodiments of the present disclosure will be more apparent from the following detailed description, taken in conjunction with the accompanying drawings, in which:

FIG. 1 is a diagram illustrating an overview of a wearable device worn on a body of a user, according to an example embodiment;

FIG. 2 is a diagram illustrating an exercise management system including a wearable device and an electronic device, according to an example embodiment;

FIG. 3 is a rear schematic view of a wearable device, according to an example embodiment.

FIG. 4 is a left side view of a wearable device, according to an example embodiment;

FIGS. 5A and 5B are diagrams illustrating a configuration of a control system of a wearable device, according to an example embodiment;

FIG. 6 is a diagram illustrating an interaction between a wearable device and an electronic device, according to an example embodiment;

FIG. 7 is a diagram illustrating a configuration of an electronic device, according to an example embodiment;

FIG. 8 is a flowchart of a method of determining the state of a three-phase motor, according to an example embodiment;

FIG. 9 illustrates a motor driver circuit, according to an example embodiment;

FIG. 10 illustrates a diagnostic circuit, according to an example embodiment;

FIG. 11A is a flowchart of a method of determining whether coils of a three-phase motor are damaged, according to an example embodiment;

FIG. 11B illustrates a control voltage, a driving voltage, and a diagnostic voltage, according to an example embodiment;

FIG. 12A is an equivalent circuit of a three-phase motor, a motor driver circuit, and a diagnostic circuit when coils of the three-phase motor and transistors of the motor driver circuit are all normal, according to an example embodiment;

FIG. 12B is an equivalent circuit of a three-phase motor, a motor driver circuit, and a diagnostic circuit when a U-phase coil of the three-phase motor is damaged, according to an example embodiment;

FIG. 12C is an equivalent circuit of a three-phase motor, a motor driver circuit, and a diagnostic circuit when a V-phase coil of the three-phase motor is damaged, according to an example embodiment;

FIG. 12D is an equivalent circuit of a three-phase motor, a motor driver circuit, and a diagnostic circuit when a W-phase coil of the three-phase motor is damaged, according to an example embodiment;

FIG. 12E is an equivalent circuit of a three-phase motor, a motor driver circuit, and a diagnostic circuit when a plurality of coils of the three-phase motor are damaged, according to an example embodiment;

FIG. 13 is a flowchart of a method of determining whether a bottom transistor of a motor driver circuit is damaged, according to an example embodiment;

FIG. 14A is an equivalent circuit of a three-phase motor, a motor driver circuit, and a diagnostic circuit when a bottom transistor of the motor driver circuit is damaged, according to an example embodiment;

FIG. 14B is an equivalent circuit of a three-phase motor, a motor driver circuit, and a diagnostic circuit when a U-phase coil of the three-phase motor and a bottom transistor of the motor driver circuit are damaged, according to an example embodiment;

FIG. 14C is an equivalent circuit of a three-phase motor, a motor driver circuit, and a diagnostic circuit when a V-phase coil of the three-phase motor and a bottom transistor of the motor driver circuit are damaged, according to an example embodiment;

FIG. 14D is an equivalent circuit of a three-phase motor, a motor driver circuit, and a diagnostic circuit when a W-phase coil of the three-phase motor and a bottom transistor of the motor driver circuit are damaged, according to an example embodiment;

FIG. 15A is a flowchart of a method of determining whether a top transistor of a motor driver circuit is damaged, according to an example embodiment;

FIG. 15B illustrates a control voltage, a driving voltage, and a diagnostic voltage, according to an example embodiment;

FIG. 16A is an equivalent circuit of a three-phase motor, a motor driver circuit, and a diagnostic circuit when a top transistor of the motor driver circuit is damaged, according to an example embodiment;

FIG. 16B is an equivalent circuit of a three-phase motor, a motor driver circuit, and a diagnostic circuit when a U-phase coil of the three-phase motor and a top transistor of the motor driver circuit are damaged, according to an example embodiment;

FIG. 16C is an equivalent circuit of a three-phase motor, a motor driver circuit, and a diagnostic circuit when a V-phase coil of the three-phase motor and a top transistor of the motor driver circuit are damaged according to an example embodiment;

FIG. 16D is an equivalent circuit of a three-phase motor, a motor driver circuit, and a diagnostic circuit when a W-phase coil of the three-phase motor and a top transistor of the motor driver circuit are damaged, according to an example embodiment;

FIG. 17 is a flowchart of a method of monitoring the state of a three-phase motor while the three-phase motor is controlled by a motor driver circuit based on pulse width modulation (PWM), according to an example embodiment;

FIG. 18 illustrates a control voltage, a driving voltage, and a diagnostic voltage that appear while a three-phase motor and a motor driver circuit operate normally, according to an example embodiment;

FIG. 19 illustrates a control voltage, a driving voltage, and a diagnostic voltage that appear while a three-phase motor or a motor driver circuit operates abnormally, according to an example embodiment;

FIG. 20 is a flowchart of a method of notifying a user of a damaged state when a three-phase motor or a motor driver circuit is damaged, according to an example embodiment; and

FIG. 21 illustrates a diagnostic circuit having a structure different from that of the diagnostic circuit shown in FIG. 9, according to an example embodiment.

### DETAILED DESCRIPTION

Hereinafter, various example embodiments will be described with reference to the accompanying drawings. However, this is not intended to limit the present disclosure to specific embodiments, and it should be understood that various modifications, equivalents, and/or alternatives of the embodiments of the present disclosure are included.

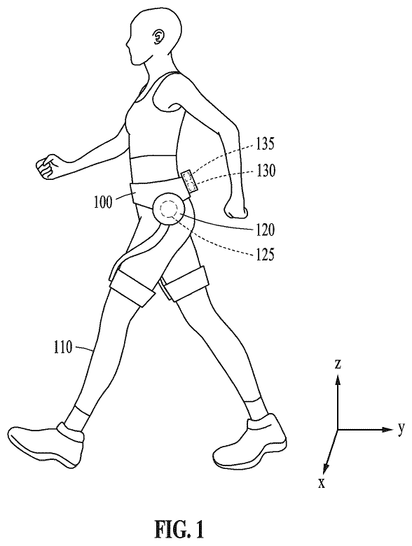

FIG. 1 is a diagram illustrating an overview of a wearable device worn on a body of a user, according to an embodiment.

Referring to FIG. 1, in an embodiment, a wearable device 100 may be a device worn on a body of a user 110 to assist the user 110 in walking, exercising, and/or working. In an embodiment, the wearable device 100 may be used to measure a physical ability (e.g., a walking ability, an exercise ability, or an exercise posture) of the user 110. In embodiments, the term “wearable device” may be replaced with “wearable robot,” “walking assistance device,” or “exercise assistance device”. The user 110 may be a human or an animal, but is not limited thereto. The wearable device 100 may be worn on a body (e.g., a lower body (the legs, ankles, knees, etc.), an upper body (the torso, arms, wrists, etc.), or the waist) of the user 110 to apply an external force such as an assistance force and/or a resistance force to a body motion of the user 110. The assistance force may be a force applied in the same direction as the body motion direction of the user 110, the force to assist a body motion of the user 110. The resistance force may be a force applied in a direction opposite to the body motion direction of the user 110, the force hindering a body motion of the user 110. The term “resistance force” may also be referred to as “exercise load”.

In an embodiment, the wearable device 100 may operate in a walking assistance mode for assisting the user 110 in walking. In the walking assistance mode, the wearable device 100 may assist the user 110 in walking by applying an assistance force generated by the driving module 120 of the wearable device 100 to the body of the user 110. The wearable device 100 may allow the user 110 to walk independently or to walk for a long time by providing a force required for walking of the user 110, to expand a walking ability of the user 110. The wearable device 100 may help in improving an abnormal walking habit or gait posture of a walker. Each “driving module” herein may comprise a motor and/or circuitry.

In an embodiment, the wearable device 100 may operate in an exercise assistance mode for enhancing the exercise effect of the user 110. In the exercise assistance mode, the wearable device 100 may hinder a body motion of the user 110 or provide resistance to a body motion of the user 110 by applying a resistance force generated by the driving module 120 to the body of the user 110. When the wearable device 100 is a hip-type wearable device that is worn on the waist (or pelvis) and legs (e.g., thighs) of the user 110, the wearable device 100 may provide an exercise load to a leg motion of the user 110 while being worn on the legs, thereby enhancing the exercise effect on the legs of the user 110. In an embodiment, the wearable device 100 may apply an assistance force to the body of the user 110 to assist the user 110 in exercising. For example, when a handicapped person or an elderly person wants to exercise wearing the wearable device 100, the wearable device 100 may provide an assistance force for assisting a body motion during the exercise process. In an embodiment, the wearable device 100 may provide an assistance force and a resistance force in combination for each exercise section or time section, in such a manner of providing an assistance force in some exercise sections and a resistance force in other exercise sections.

In an embodiment, the wearable device 100 may operate in a physical ability measurement mode for measuring a physical ability of the user 110. The wearable device 100 may measure motion information of the user 110 using sensors (e.g., an angle sensor 125 and an inertial measurement unit (IMU) 135) provided in the wearable device 100 while the user 110 is walking or exercising, and evaluate the physical ability of the user 110 based on the measured motion information. For example, a gait index or an exercise ability indicator (e.g., the muscular strength, endurance, balance, or exercise posture) of the user 110 may be estimated through the motion information of the user 110 measured by the wearable device 100. The physical ability measurement mode may include an exercise posture measurement mode for measuring an exercise posture of the user 110.

In various embodiments of the present disclosure, for convenience of description, the wearable device 100 is described as an example of a hip-type wearable device, as illustrated in FIG. 1, but the embodiments are not limited thereto. As described above, the wearable device 100 may be worn on another body part (e.g., the upper arms, lower arms, hands, calves, and feet) other than the waist and legs (particularly, the thighs), and the shape and configuration of the wearable device 100 may vary depending on the body part on which the wearable device 100 is worn.

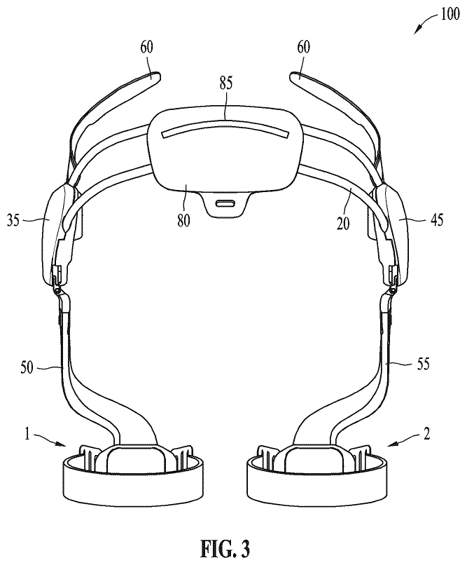

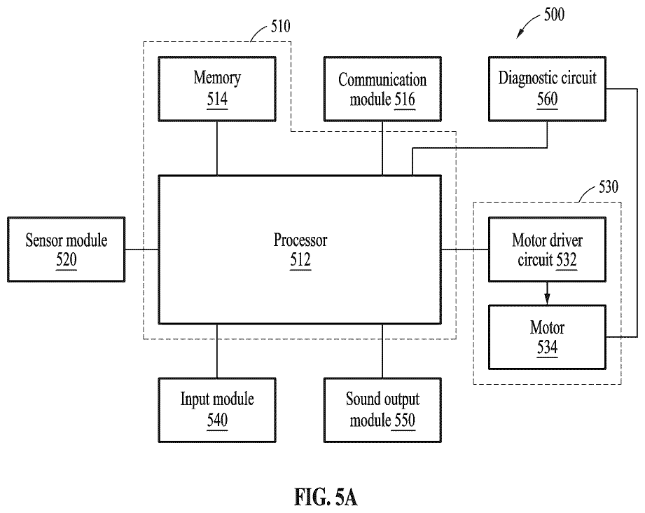

According to an embodiment, the wearable device 100 may include a support frame (e.g., leg support frames 50 and 55 and a waist support frame 20 of FIG. 3) configured to support the body of the user 110 when the wearable device 100 is worn on the body of the user 110, a sensor module (e.g., a sensor module 520 of FIG. 5A) configured to obtain sensor data including motion information about a body motion (e.g., a leg motion and an upper body motion) of the user 110, the driving module 120 (e.g., driving modules 35 and 45 of FIG. 3) configured to generate a torque to be applied to the legs of the user 110, and a control module 130 (e.g., a control module 510 of FIGS. 5A and 5B, comprising circuitry) configured to control the wearable device 100.

According to an embodiment, the wearable device 100 may further include a diagnostic circuit (e.g., a diagnostic circuit 560 of FIG. 5A) configured to diagnose the state of the driving module 120. The combination of the control module 130 and the diagnostic circuit of the wearable device 100 may be referred to as a diagnostic module.

The sensor module may include the angle sensor 125 and the IMU 135. The angle sensor 125 may measure the rotational angle of a leg support frame of the wearable device 100 corresponding to the hip joint angle value of the user 110. The rotational angle of the leg support frame measured by the angle sensor 125 may be estimated as the hip joint angle value (or leg angle value) of the user 110. The angle sensor 125 may include, for example, an encoder and/or a Hall sensor. In an embodiment, the angle sensor 125 may be present near each of the right hip joint and the left hip joint of the user 110. The IMU 135 may include an acceleration sensor and/or an angular velocity sensor, and may measure a change in acceleration and/or angular velocity according to a motion of the user 110. The IMU 135 may measure, for example, an upper body motion value of the user 110 corresponding to a motion value of a waist support frame (or a base body (a base body 80 of FIG. 3)) of the wearable device 100. The motion value of the waist support frame measured by the IMU 135 may be estimated as the upper body motion value of the user 110.

In an embodiment, the control module 130 and the IMU 135 may be arranged within the base body (e.g., the base body 80 of FIG. 3) of the wearable device 100. The base body may be positioned on the lumbar region (an area of the lower back) of the user 110 while the user 110 is wearing the wearable device 100. The base body may be formed or attached to the outer side of the waist support frame of the wearable device 100. The base body may be mounted on the lumbar region of the user 110 to provide a cushioning feeling to the lower back of the user 110 and may support the lower back of the user 110 together with the waist support frame.

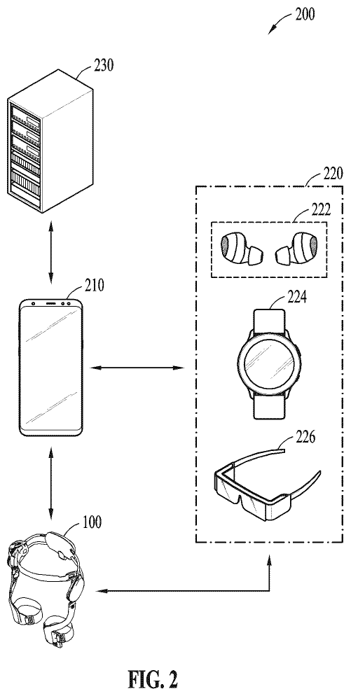

FIG. 2 is a diagram illustrating an exercise management system including a wearable device and an electronic device, according to an embodiment.

Referring to FIG. 2, an exercise management system 200 may include the wearable device 100 to be worn on a body of a user, an electronic device 210, another wearable device 220, and a server 230. In an embodiment, at least one (e.g., the other wearable device 220 or the server 230) of these devices may be omitted from the exercise management system 200, or one or more other devices (e.g., an exclusive controller device of the wearable device 100) may be added thereto.

In an embodiment, the wearable device 100 may be worn on a body of the user in the walking assistance mode to assist a motion of the user. For example, the wearable device 100 may be worn on the legs of the user to help the user in walking by generating an assistance force for assisting a leg motion of the user.

In an embodiment, the wearable device 100 may generate a resistance force for hindering a body motion of the user or an assistance force for assisting a body motion of the user and apply the generated resistance force or assistance force to the body of the user to enhance the exercise effect of the user in an exercise assistance mode. In the exercise assistance mode, the user may select, through the electronic device 210, an exercise program (e.g., squat, split lunge, dumbbell squat, lunge and knee up, stretching, or the like) to perform using the wearable device 100 and/or an exercise intensity to be applied to the wearable device 100. The wearable device 100 may control a driving module of the wearable device 100 according to the exercise program selected by the user and obtain sensor data including motion information of the user through a sensor module. The wearable device 100 may adjust the strength of the resistance force or assistance force applied to the user according to the exercise intensity selected by the user. For example, the wearable device 100 may control the driving module to generate a resistance force corresponding to the exercise intensity selected by the user.

In an embodiment, the wearable device 100 may be used to measure a physical ability of the user in interoperation with the electronic device 210. The wearable device 100 may operate in a physical ability measurement mode, which is a mode for measuring a physical ability of the user, under the control of the electronic device 210, and may transmit sensor data obtained by a motion of the user in the physical ability measurement mode to the electronic device 210. The electronic device 210 may estimate the physical ability of the user by analyzing the sensor data received from the wearable device 100.

The electronic device 210 may communicate with the wearable device 100 and may remotely control the wearable device 100 or provide the user with state information about a state (e.g., a booting state, a charging state, a sensing state, or an error state) of the wearable device 100. The electronic device 210 may receive the sensor data obtained by a sensor in the wearable device 100 from the wearable device 100 and estimate the physical ability of the user or an exercise result based on the received sensor data. In an embodiment, when the user exercises wearing the wearable device 100, the wearable device 100 may obtain sensor data including motion information of the user using sensors and transmit the obtained sensor data to the electronic device 210. The electronic device 210 may extract a motion value of the user from the sensor data and evaluate an exercise posture of the user based on the extracted motion value. The electronic device 210 may provide the user with an exercise posture measured value and exercise posture evaluation information related to the exercise posture of the user through a GUI.

In an embodiment, the electronic device 210 may execute a program (e.g., an application) configured to control the wearable device 100, and the user may adjust an operation or a set value of the wearable device 100 (e.g., the magnitude of torque output from a driving module (e.g., the driving modules 35 and 45 of FIG. 3), the volume of audio output from a sound output module (e.g., a sound output module 550 of FIGS. 5A and 5B), or the brightness of a lighting unit (e.g., a lighting unit 85 of FIG. 3) through the corresponding program. The program executed by the electronic device 210 may provide a GUI for interaction with the user. The electronic device 210 may be a device in various forms. For example, the electronic device 210 may include a portable communication device (e.g., a smart phone), a computer device, an access point, a portable multimedia device, or a home appliance (e.g., a television, an audio device, or a projector device), but is not limited thereto.

According to an embodiment, the electronic device 210 may be connected to the server 230 using short-range wireless communication or cellular communication. The server 230 may receive user profile information of the user who uses the wearable device 100 from the electronic device 210 and store and manage the received user profile information. The user profile information may include, for example, information about at least one of the name, age, gender, height, weight, or body mass index (BMI). The server 230 may receive exercise history information about an exercise performed by the user from the electronic device 210 and store and manage the received exercise history information. The server 230 may provide the electronic device 210 with various exercise programs or physical ability measurement programs that may be provided to the user.

According to an embodiment, the wearable device 100 and/or the electronic device 210 may be connected to the other wearable device 220. The other wearable device 220 may include, for example, wireless earphones 222, a smart watch 224, or smart glasses 226, but is not limited thereto. In an embodiment, the smart watch 224 may measure a biosignal including heart rate information of the user and transmit the measured biosignal to the electronic device 210 and/or the wearable device 100. The electronic device 210 may estimate the heart rate information (e.g., the current heart rate, maximum heart rate, and average heart rate) of the user based on the biosignal received from the smart watch 224 and provide the estimated heart rate information to the user.

In an embodiment, the exercise result information, physical ability information, and/or exercise posture evaluation information evaluated by the electronic device 210 may be transmitted to the other wearable device 220 and provided to the user through the other wearable device 220. State information of the wearable device 100 may also be transmitted to the other wearable device 220 and provided to the user through the other wearable device 220. In an embodiment, the wearable device 100, the electronic device 210, and the other wearable device 220 may be connected to each other through wireless communication (e.g., Bluetooth communication or Wi-Fi communication).

In an embodiment, the wearable device 100 may provide (or output) feedback (e.g., visual feedback, auditory feedback, or haptic feedback) corresponding to the state of the wearable device 100 according to the control signal received from the electronic device 210. For example, the wearable device 100 may provide visual feedback through the lighting unit (e.g., the lighting unit 85 of FIG. 3) and provide auditory feedback through the sound output module (e.g., the sound output module 550 of FIGS. 5A and 5B). The wearable device 100 may include a haptic module and provide haptic feedback in the form of vibration to the body of the user through the haptic module. The electronic device 210 may also provide (or output) feedback (e.g., visual feedback, auditory feedback, or haptic feedback) corresponding to the state of the wearable device 100.

In an embodiment, the electronic device 210 may present a personalized exercise goal to the user in the exercise assistance mode. The personalized exercise goal may include respective target amounts of exercise for exercise types (e.g., strength exercise, balance exercise, and aerobic exercise) desired by the user, determined by the electronic device 210 and/or the server 230. When the server 230 determines a target amount of exercise, the server 230 may transmit information about the determined target amount of exercise to the electronic device 210. The electronic device 210 may personalize and present the target amounts of exercise for the exercise types, such as strength exercise, aerobic exercise, and balance exercise, according to a desired exercise program (e.g., squat, split lunge, or a lunge and knee up) and/or the physical characteristics (e.g., the age, height, weight, and BMI) of the user. The electronic device 210 may display a GUI screen displaying the target amounts of exercise for the respective exercise types on a display.

In an embodiment, the electronic device 210 and/or the server 230 may include a database in which information about a plurality of exercise programs to be provided to the user through the wearable device 100 is stored. To achieve an exercise goal of the user, the electronic device 210 and/or the server 230 may recommend an exercise program suitable for the user. The exercise goal may include, for example, at least one of muscle strength improvement, physical strength improvement, cardiovascular endurance improvement, core stability improvement, flexibility improvement, or symmetry improvement. The electronic device 210 and/or the server 230 may store and manage the exercise program performed by the user, the results of performing the exercise program, and the like.

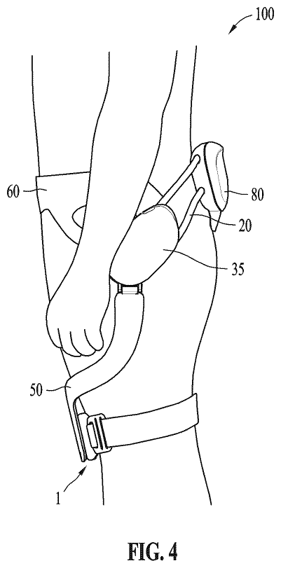

FIG. 3 is a rear schematic view of a wearable device, according to an embodiment. FIG. 4 is a left side view of the wearable device, according to an embodiment.

Referring to FIGS. 3 and 4, the wearable device 100 according to an embodiment may include the base body 80, the waist support frame 20, the driving modules 35 and 45, the leg support frames 50 and 55, thigh fastening portions 1 and 2, and a waist fastening portion 60. The base body 80 may include the lighting unit 85. In an embodiment, at least one (e.g., the lighting unit 85) of these components may be omitted from the wearable device 100, or one or more other components (e.g., a haptic module) may be added to the wearable device 100.

The base body 80 may be positioned on the lumbar region of a user while the user is wearing the wearable device 100. The base body 80 may be mounted on the lumbar region of the user to provide a cushioning feeling to the lower back of the user and may support the lower back of the user. The base body 80 may be hung on the hip region (an area of the hips) of the user to prevent or reduce chances of the wearable device 100 from being separated downward due to gravity while the user is wearing the wearable device 100. The base body 80 may distribute a portion of the weight of the wearable device 100 to the lower back of the user while the user is wearing the wearable device 100. The base body 80 may be connected, directly or indirectly, to the waist support frame 20. Waist support frame connecting elements (not shown) to be connected, directly or indirectly, to the waist support frame 20 may be provided at both end portions of the base body 80.

In an embodiment, the lighting unit 85 may be arranged on the outer side of the base body 80. The lighting unit 85 may include a light source (e.g., a light-emitting diode (LED)). The lighting unit 85 may emit light under the control of a control module (not shown) (e.g., the control module 510 of FIGS. 5A and 5B). In some embodiments, the control module, comprising circuitry, may control the lighting unit 85 to provide (or output) visual feedback corresponding to the state of the wearable device 100 to the user through the lighting unit 85.

The waist support frame 20 may extend from both end portions of the base body 80. The lumbar region of the user may be accommodated inside the waist support frame 20. The waist support frame 20 may include at least one rigid body beam. Each beam may be in a curved shape having a preset curvature to enclose the lumbar region of the user. The waist fastening portion 60 may be connected, directly or indirectly, to an end portion of the waist support frame 20. The driving modules 35 and 45 may be connected, directly or indirectly, to the waist support frame 20.

In an embodiment, the control module, an IMU (not shown) (e.g., the IMU 135 of FIG. 1 or an IMU 522 of FIG. 5B), a communication module (not shown) (e.g., a communication module 516 of FIGS. 5A and 5B), and a battery (not shown) may be arranged inside the base body 80. The base body 80 may protect the control module, the IMU, the communication module, and the battery. The control module may generate a control signal for controlling the operation of the wearable device 100. The control module may include a control circuit including a processor configured to control actuators of the driving modules 35 and 45 and a memory. The control module may further include a power supply module (not shown) configured to supply power from the battery to each of the components of the wearable device 100.

In an embodiment, the wearable device 100 may include a sensor module (not shown) (e.g., the sensor module 520 of FIG. 5A) configured to obtain sensor data from at least one sensor. The sensor module may obtain sensor data that changes according to a motion of the user. In an embodiment, the sensor module may obtain sensor data including motion information of the user and/or motion information of the components of the wearable device 100. The sensor module may include, for example, an IMU (e.g., the IMU 135 of FIG. 1 or the IMU 522 of FIG. 5B) configured to measure an upper body motion value of the user or a motion value of the waist support frame 20 and an angle sensor (e.g., the angle sensor 125 of FIG. 1 or a first angle sensor 524 and a second angle sensor 524-1 of FIG. 5B) configured to measure a hip joint angle value of the user or a motion value of the leg support frames 50 and 55, but is not limited thereto. For example, the sensor module may further include at least one of a position sensor, a temperature sensor, a biosignal sensor, or a proximity sensor.

The waist fastening portion 60 may be connected, directly or indirectly, to the waist support frame 20 to fasten the waist support frame 20 to the waist of the user. The waist fastening portion 60 may include, for example, a pair of belts.

The driving modules 35 and 45 may generate an external force (or torque) to be applied to the body of the user based on the control signal generated by the control module. For example, the driving modules 35 and 45 may generate an assistance force or resistance force to be applied to the legs of the user. In an embodiment, the driving modules 35 and 45 may include a first driving module 45 disposed in a position corresponding to a position of a right hip joint of the user, and a second driving module 35 disposed in a position corresponding to a position of a left hip joint of the user. The first driving module 45 may include a first actuator and a first joint member, and the second driving module 35 may include a second actuator and a second joint member. The first actuator may provide power to be transmitted to the first joint member, and the second actuator may provide power to be transmitted to the second joint member. The first actuator and the second actuator may each include a motor configured to generate power (or a torque) by receiving electric power from the battery. When the motor is supplied with electric power and driven, the motor may generate a force (an assistance force) for assisting a body motion of the user or a force (a resistance force) for hindering a body motion of the user. For example, the motor may be a three-phase motor. In an embodiment, the control module may adjust the strength and direction of the force generated by the motor by adjusting the voltage and/or current supplied to the motor.

In an embodiment, the first joint member and the second joint member may receive power from the first actuator and the second actuator, respectively, and may apply an external force to the body of the user based on the received power. The first joint member and the second joint member may be arranged at positions corresponding to the joints of the user, respectively. One side of the first joint member may be connected, directly or indirectly, to the first actuator, and the other side of the first joint member may be connected, directly or indirectly, to a first leg support frame 55. The first joint member may be rotated by the power received from the first actuator. An encoder or a Hall sensor that may operate as an angle sensor configured to measure the rotational angle of the first joint member (corresponding to the joint angle of the user) may be arranged on one side of the first joint member. One side of the second joint member may be connected, directly or indirectly, to the second actuator, and the other side of the second joint member may be connected, directly or indirectly, to a second leg support frame 50. The second joint member may be rotated by the power received from the second actuator. An encoder or a Hall sensor that may operate as an angle sensor configured to measure the rotational angle of the second joint member may be arranged on one side of the second joint member.

In an embodiment, the first actuator may be arranged in a lateral direction of the first joint member, and the second actuator may be arranged in a lateral direction of the second joint member. A rotation axis of the first actuator and a rotation axis of the first joint member may be spaced apart from each other, and a rotation axis of the second actuator and a rotation axis of the second joint member may also be spaced apart from each other. However, embodiments are not limited thereto, and an actuator and a joint member may share a rotation axis. In an embodiment, each actuator may be spaced apart from a corresponding joint member. In this case, each of the driving modules 35 and 45 may further include a power transmission module (not shown) configured to transmit power from the actuator to the joint member. The power transmission module may be a rotary body, such as a gear, or a longitudinal member, such as a wire, a cable, a string, a spring, a belt, or a chain. However, the scope of the embodiment is not limited by the positional relationship between an actuator and a joint member and the power transmission structure described above.

In an embodiment, the leg support frame 50, 55 may support a leg (e.g., a thigh) of the user when the wearable device 100 is worn on the leg of the user. For example, the leg support frames 50 and 55 may transmit power (a torque) generated by the driving modules 35 and 45 to the thighs of the user, and the power may act as an external force to be applied to a motion of the legs of the user. As one end portions of the leg support frames 50 and 55 are connected, directly or indirectly, to the joint members to rotate and the other end portions of the leg support frames 50 and 55 are connected, directly or indirectly, to the thigh fastening portions 1 and 2, the leg support frames 50 and 55 may transmit the power generated by the driving modules 35 and 45 to the thighs of the user while supporting the thighs of the user. For example, the leg support frames 50 and 55 may push or pull the thighs of the user. The leg support frames 50 and 55 may extend in the longitudinal direction of the thighs of the user. The leg support frames 50 and 55 may be bent to surround at least a portion of the circumference of the thighs of the user. The leg support frames 50 and 55 may include the first leg support frame 55 configured to support the right leg of the user and the second leg support frame 50 configured to support the left leg of the user.

The thigh fastening portions 1 and 2 may be connected, directly or indirectly, to the leg support frames 50 and 55 and may fix the leg support frames 50 and 55 to the thigh. The thigh fastening portions 1 and 2 may include a first thigh fastening portion 2 configured to fasten the first leg support frame 55 to the right thigh of the user and a second thigh fastening portion 1 configured to fasten the second leg support frame 50 to the left thigh of the user.

In an embodiment, the first thigh fastening portion 2 may include a first cover, a first fastening frame, and a first strap, and the second thigh fastening portion 1 may include a second cover, a second fastening frame, and a second strap. In an embodiment, the first cover and the second cover may apply torques generated by the driving modules 35 and 45 to the thighs of the user. For example, the first cover and the second cover may be arranged on one sides of the thighs of the user to push or pull the thigh of the user. The first cover and the second cover may be arranged on the front surfaces of the thighs of the user. The first cover and the second cover may be arranged in the circumferential directions of the thighs of the user. The first cover and the second cover may extend to both sides from the other end portions of the leg support frames 50 and 55 and may include curved surfaces corresponding to the thighs of the user. One ends of the first cover and the second cover may be connected to the fastening frames, and the other ends thereof may be connected to the straps.

The first fastening frame and the second fastening frame may be arranged, for example, to surround at least some portions of the circumferences of the thighs of the user, thereby preventing or reducing chances of the thighs of the user from being separated from the leg support frames 50 and 55. The first fastening frame may have a fastening structure that connects the first cover and the first strap, and the second fastening frame may have a fastening structure that connects the second cover and the second strap.

The first strap may enclose the remaining portion of the circumference of the right thigh of the user that is not covered by the first cover and the first fastening frame, and the second strap may enclose the remaining portion of the circumference of the left thigh of the user that is not covered by the second cover and the second fastening frame. The first strap and the second strap may include, for example, an elastic material (e.g., a band).

FIGS. 5A and 5B are diagrams illustrating a configuration of a control system of a wearable device according to an embodiment.

Referring to FIG. 5A, the wearable device/apparatus 100 may be controlled by a control system 500. The control system 500 may include the control module 510, the communication module 516, the sensor module 520, a driving module 530, an input module 540, and the sound output module 550. In an embodiment, at least one (e.g., the sound output module 550) of these components may be omitted from the control system 500, or one or more other components (e.g., a haptic module) may be added to the control system 500.

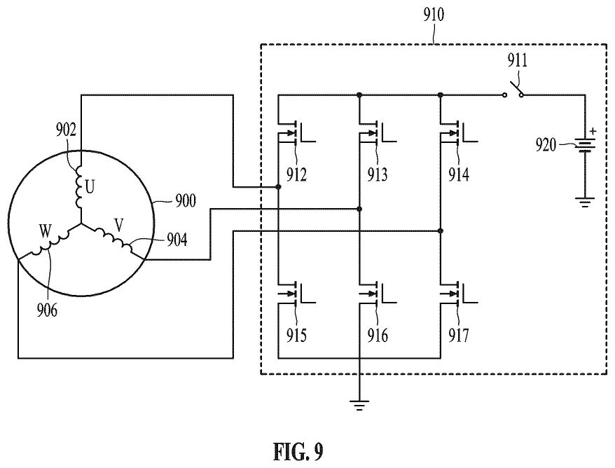

According to an embodiment, the control system 500 may further include a diagnostic circuit 560 configured to diagnose the diagnostic state of the driving module 530. The structure of the diagnostic circuit 560 is described in detail with reference to FIG. 10.

The driving module 530 may include a motor 534 configured to generate power (e.g., a torque) and a motor driver circuit 532 configured to drive the motor 534. Although FIG. 5A illustrates the driving module 530 including one motor driver circuit 532 and one motor 534, the example of FIG. 5A is merely an example. Referring to FIG. 5B, a control system 500-1 may include a plurality of (e.g., two or more) motor driver circuits 532 and 532-1, a plurality of (e.g., two or more) motors 534 and 534-1, and a plurality of (e.g., two or more) diagnostic circuits 560 and 560-1. The driving module 530 including the motor driver circuit 532 and the motor 534 may correspond to the first driving module 45 of FIG. 3, and a driving module 530-1 including the motor driver circuit 532-1 and the motor 534-1 may correspond to the second driving module 35 of FIG. 3. The following descriptions of the motor driver circuit 532, the motor 534, and the diagnostic circuit 560 may also be respectively applicable to the motor driver circuit 532-1, the motor 534-1, and the diagnostic circuit 560-1 illustrated in FIG. 5B.

Referring back to FIG. 5A, the sensor module 520 may include a sensor circuit including at least one sensor. The sensor module 520 may obtain sensor data including motion information of a user or motion information of the wearable device 100. The sensor module 520 may transmit the obtained sensor data to the control module 510. The sensor module 520 may include an IMU 522 and an angle sensor (e.g., a first angle sensor 524 and a second angle sensor 524-1) as illustrated in FIG. 5B. The IMU 522 may measure an upper body motion value of the user. For example, the IMU 522 may sense X-axis, Y-axis, and Z-axis accelerations and X-axis, Y-axis, and Z-axis angular velocities according to a motion of the user. The IMU 522 may be used to measure, for example, at least one of a forward and backward tilt, a left and right tilt, or a rotation of the body of the user. In addition, the IMU 522 may obtain motion values (e.g., acceleration values and angular velocity values) of a waist support frame (e.g., the waist support frame 20 of FIG. 3) of the wearable device 100. The motion values of the waist support frame may correspond to upper body motion values of the user.

The angle sensor may measure a hip joint angle value according to a motion of a leg of the user. Sensor data that may be measured by the angle sensor may include, for example, a hip joint angle value of a right leg, a hip joint angle value of a left leg, and information on a motion direction of a leg. For example, the first angle sensor 524 of FIG. 5B may obtain the hip joint angle value of the right leg of the user, and the second angle sensor 524-1 may obtain the hip joint angle value of the left leg of the user. The first angle sensor 524 and the second angle sensor 524-1 may each include, for example, an encoder and/or a hall sensor. Further, the angle sensors may obtain motion values of the leg support frames of the wearable device 100. For example, the first angle sensor 524 may obtain a motion value of the first leg support frame 55, and the second angle sensor 524-1 may obtain a motion value of the second leg support frame 50. The motion values of the leg support frames may correspond to the hip joint angle values.

In an embodiment, the sensor module 520 may further include at least one of a position sensor configured to obtain a position value of the wearable device 100, a proximity sensor configured to sense the proximity of an object, a biosignal sensor configured to detect a biosignal of the user, or a temperature sensor configured to measure an ambient temperature.

The input module 540 may receive a command or data to be used by another component (e.g., the processor 512) of the wearable apparatus 100 from the outside (e.g., the user) of the wearable apparatus 100. The input module 540 may include an input component circuit. The input module 540 may include, for example, a key (e.g., a button) or a touch screen.

The sound output module 550 may output a sound signal to the outside of the wearable apparatus 100. The sound output module 550 may provide auditory feedback to the user. For example, the sound output module 550 may include a speaker configured to play back a guiding sound signal (e.g., an operation start sound, an operation error alarm, or an exercise start alarm), music content, or a guiding voice for auditorily informing predetermined information (e.g., exercise result information or exercise posture evaluation information).

In an embodiment, the control system 500 may further include a battery (not shown) configured to supply power to each component of the wearable device 100. The wearable device 100 may convert the power of the battery into power suitable for an operating voltage of each component of the wearable device 100 and supply the converted power to each component.

The driving module 530 may generate an external force to be applied to a leg of the user under the control of the control module 510. The driving module 530 may generate a torque to be applied to the legs of the user based on a control signal generated by the control module 510. The control module 510 may transmit the control signal to the motor driver circuit 532. The motor driver circuit 532 may control the operation of the motor 534 by generating a current signal (or voltage signal) corresponding to the control signal and supplying the generated current signal (or voltage signal) to the motor 534. In some cases, the current signal may not be supplied to the motor 534. When the motor 534 is supplied with the current signal and driven, the motor 534 may generate a torque for an assistance force for assisting a leg motion of the user or a resistance force for hindering a leg motion of the user.

The control module 510 may control the overall operation of the wearable device 100 and may generate a control signal for controlling each component (e.g., the communication module 516 or the driving module 530). The control module 510 may include the processor 512 and a memory 514. Each “module” herein may comprise circuitry.

The processor 512 may execute, for example, software to control at least one other component (e.g., a hardware or software component) of the wearable device 100 connected, directly or indirectly, to the processor 512, and may perform a variety of data processing or computation. The software may include an application for providing a graphical user interface (GUI). According to an embodiment, as at least part of data processing or computation, the processor 512 may store instructions or data received from another component (e.g., the communication module 516, comprising communication circuitry) in the memory 514, process the instructions or data stored in the memory 514, and store result data obtained as a result of processing in the memory 514. According to an embodiment, the processor 512 may include a main processor (e.g., a central processing unit (CPU) or an application processor (AP)) or an auxiliary processor (e.g., a graphics processing unit (GPU), a neural processing unit (NPU), an image signal processor (ISP), a sensor hub processor, or a communication processor (CP)) that is operable independently of, or in conjunction with the main processor. The auxiliary processor may be implemented separately from the main processor or as part of the main processor.

The memory 514 may store a variety of data used by at least one component (e.g., the processor 512) of the control module 510. The data may include, for example, software, sensor data, and input data or output data for instructions related thereto. The memory 514 may include a volatile memory or a non-volatile memory (e.g., a random-access memory (RAM), a dynamic RAM (DRAM), or a static RAM (SRAM)).

The communication module 516 may support establishing a direct (e.g., wired) communication channel or a wireless communication channel between the control module 510 and another component of the wearable device 100 or an external electronic device (e.g., the electronic device 210 or the other wearable device 220 of FIG. 2) and performing communication via the established communication channel. The communication module 516 may include a communication circuit configured to perform a communication function. For example, the communication module 516 may receive a control signal from an electronic device (e.g., the electronic device 210) and transmit the sensor data obtained by the sensor module 520 to the electronic device. The communication module 516 may include one or more CPs (not shown) that are operable independently of the processor 512 and that support direct (e.g., wired) communication or wireless communication. According to an embodiment, the communication module 516 may include a wireless communication module (e.g., a cellular communication module, a short-range wireless communication module, or a global navigation satellite system (GNSS) communication module), and/or a wired communication module. A corresponding one of these communication modules may communicate with another component of the wearable device 100 and/or an external electronic device via a short-range communication network (e.g., such as Bluetooth™, wireless-fidelity (Wi-Fi), or infrared data association (IrDA)), or a long-range communication network, such as a legacy cellular network, a 5G network, a next-generation communication network, the Internet, or a computer network (e.g., a local area network (LAN) or a wide area network (WAN)).

In an embodiment, each of the control systems 500 and 500-1 may further include a haptic module (not shown). The haptic module may provide haptic feedback to the user under the control of the processor 512. The haptic module may convert an electrical signal into a mechanical stimulus (e.g., a vibration or a movement) or an electrical stimulus which may be recognized by the user via his or her tactile sensation or kinesthetic sensation. The haptic module may include a motor, a piezoelectric element, or an electrical stimulation device. In an embodiment, the haptic module may be positioned in at least one of the base body (e.g., the base body 80), the first thigh fastening portion 2, or the second thigh fastening portion 1.

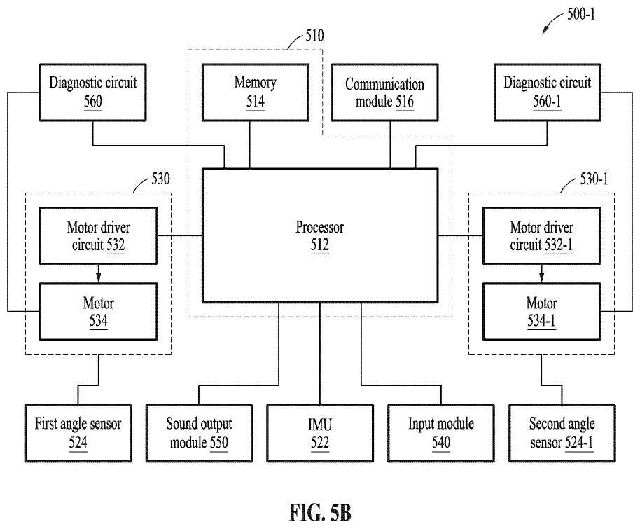

FIG. 6 is a diagram illustrating an interaction between a wearable device and an electronic device, according to an embodiment.

Referring to FIG. 6, the wearable device 100 may communicate with the electronic device 210. For example, the electronic device 210 may be a user terminal of a user who uses the wearable device 100 or a controller device dedicated to the wearable device 100. In an embodiment, the wearable device 100 and the electronic device 210 may be connected to each other through short-range wireless communication (e.g., Bluetooth communication or Wi-Fi communication).

In an embodiment, the electronic device 210 may check a state of the wearable device 100 or execute an application to control or operate the wearable device 100. A screen of a user interface (UI) may be displayed to control an operation of the wearable device 100 or determine an operation mode of the wearable device 100 on a display 212 of the electronic device 210 through the execution of the application. The UI may be, for example, a graphical user interface (GUI).

In an embodiment, the user may input an instruction for controlling the operation of the wearable device 100 (e.g., an execution instruction to a walking assistance mode, an exercise assistance mode, or a physical ability measurement mode) or change settings of the wearable device 100 through a GUI screen on the display 212 of the electronic device 210. The electronic device 210 may generate a control instruction (or control signal) corresponding to an operation control instruction or a setting change instruction input by the user and transmit the generated control instruction to the wearable device 100. The wearable device 100 may operate according to the received control instruction and transmit a control result according to the control instruction and/or sensor data measured by the sensor module of the wearable device 100 to the electronic device 210. The electronic device 210 may provide the user with result information (e.g., walking ability information, exercise ability information, or exercise posture evaluation information) derived by analyzing the control result and/or the sensor data through the GUI screen.

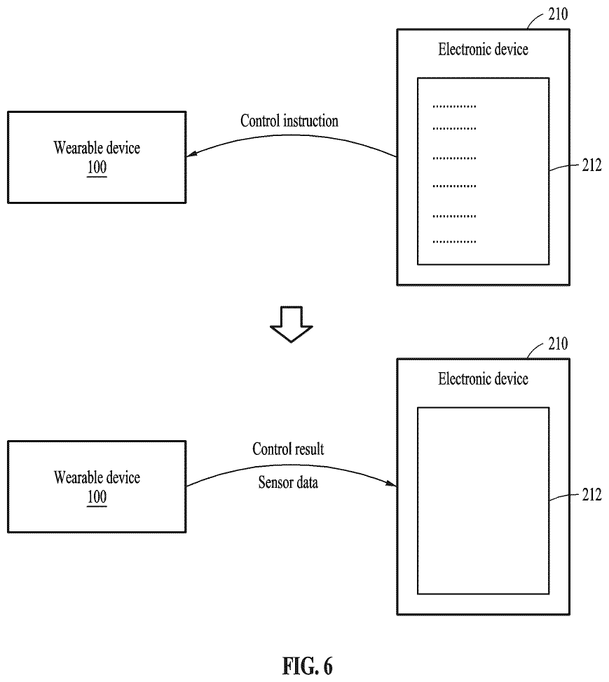

FIG. 7 is a diagram illustrating a configuration of an electronic device, according to an embodiment.

Referring to FIG. 7, the electronic device 210 may include a processor 710, a memory 720, a communication module 730, a display module 740, a sound output module 750, and an input module 760. In an embodiment, at least one (e.g., the sound output module 750) of these components may be omitted from the electronic device 210, or one or more other components (e.g., a sensor module and a battery) may be added to the electronic device 210.

The processor 710 may control at least one other component (e.g., a hardware or software component) of the electronic device 210, and may perform a variety of data processing or computation. According to an embodiment, as at least part of data processing or computation, the processor 710 may store instructions or data received from another component (e.g., the communication module 730) in the memory 720, process the instructions or data stored in the memory 720, and store result data in the memory 720.

In an embodiment, the processor 710 may include a main processor (e.g., a CPU or an AP) or an auxiliary processor (e.g., a GPU, an NPU, an ISP, a sensor hub processor, or a CP) that is operable independently of or in conjunction with the main processor.

The memory 720 may store a variety of data used by at least one component (e.g., the processor 710 or the communication module 730 comprising communication circuitry) of the electronic device 210. The data may include, for example, a program (e.g., an application), and input data or output data for instructions related thereto. The memory 720 may include at least one instruction executable by the processor 710. The memory 720 may include a volatile memory or a non-volatile memory.

The communication module 730, comprising communication circuitry, may support establishing a direct (e.g., wired) communication channel or a wireless communication channel between the electronic device 210 and another electronic device (e.g., the wearable device 100, the other wearable device 220, or the server 230) and performing communication via the established communication channel. The communication module 730 may include a communication circuit configured to perform a communication function. The communication module 730 may include one or more CPs that are operable independently of the processor 710 (e.g., an AP) and that support direct (e.g., wired) communication or wireless communication. According to an embodiment, the communication module 730/516 may include a wireless communication module configured to perform wireless communication (e.g., a Bluetooth communication module, a cellular communication module, a Wi-Fi communication module, or a GNSS communication module) or a wired communication module (e.g., a LAN communication module or a power line communication (PLC) module). For example, the communication module 730 may transmit a control instruction to the wearable device 100 and receive, from the wearable device 100, at least one of sensor data including body motion information of the user who is wearing the wearable device 100, state data of the wearable device 100, or control result data corresponding to the control instruction.

The display module 740 may visually provide information to the outside (e.g., the user) of the electronic device 210. The display module 740 may include, for example, a liquid-crystal display (LCD) or organic light-emitting diode (OLED) display, a hologram device, or a projector device. The display module 740 may further include a control circuit configured to control the driving of a display. In an embodiment, the display module 740 may further include a touch sensor set to sense a touch or a pressure sensor set to sense the intensity of a force generated by the touch.

The sound output module 750 may output sound signals to the outside of the electronic device 210. The sound output module 750 may include a guide sound signal (e.g., a driving start sound or an operation error notification sound) based on a state of the wearable device 100 and a speaker for playing musical content or a guide voice. When it is determined that the wearable device 100 is not properly worn on the body of the user, the sound output module 750 may output a guiding voice for informing the user is wearing the wearable device 100 abnormally or for guiding the user to wear the wearable device 100 normally. The sound output module 750 may output, for example, a guiding voice corresponding to exercise evaluation information or exercise result information obtained by evaluating an exercise of the user.

The Input module 760 may receive a command or data to be used by a component (e.g., the processor 710) of the electronic device 210 from the outside (e.g., the user) of the electronic device 210. The input module 760 may include an input component circuit and may receive a user input. The input module 760 may include, for example, a key (e.g., a button) or a touch screen.

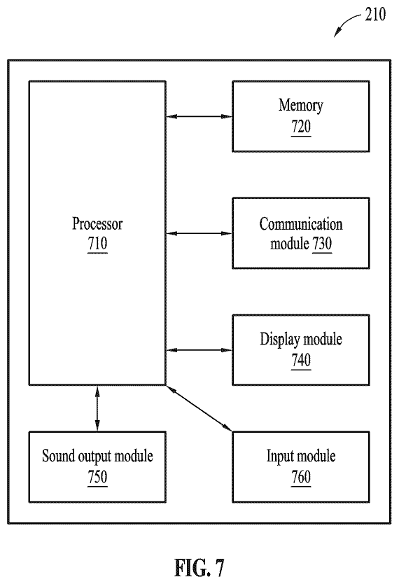

FIG. 8 is a flowchart of a method of determining the state of a three-phase motor, according to an embodiment.

Operations 810 to 830 below may be performed by a wearable device (e.g., the wearable device 100 of FIG. 1). For example, operations 810 to 830 may be performed by a diagnostic module of the wearable device. The diagnostic module of the wearable device may include a processor (e.g., the processor 512 of FIG. 5A) and a diagnostic circuit (e.g., the diagnostic circuit 560 of FIG. 5). The processor may include a microcontroller unit (MCU).

For example, operation 810 may be performed when it is determined that a user is wearing the wearable device. For example, operation 810 may be performed when the wearable device is turned on.

In operation 810, the processor of the diagnostic module may apply a control voltage to an input terminal of the diagnostic circuit that is electrically connected, directly or indirectly, to terminals of a motor (e.g., the motor 534 of FIG. 5A). For example, the motor may be a three-phase motor. The structure of the diagnostic circuit is described in detail below with reference to FIG. 10.

According to an embodiment, the processor may apply the control voltage to the diagnostic circuit by outputting a control signal to a general-purpose input/output (GPIO) port of the processor. For example, the inside of the GPIO port may be configured in a push-pull mode or an open-drain mode. The GPIO port may be in a high-impedance state while a control signal is not output. For example, the control voltage may be a voltage between 0 volts (V) and 5 V and is not limited to the described embodiment.

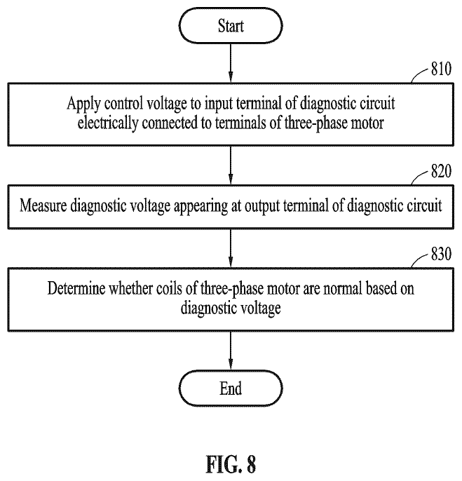

According to an embodiment, the diagnostic module may apply the control voltage to the input terminal of the diagnostic circuit while a driving voltage is not applied to the motor. The driving voltage may be a voltage applied to a motor driver circuit (e.g., the motor driver circuit 532 of FIG. 5A). When the driving voltage is applied to the motor driver circuit, the motor may be controlled based on pulse width modulation (PWM). The structure of the motor driver circuit is described in detail below with reference to FIG. 9.

In operation 820, the processor of the diagnostic module may measure a diagnostic voltage appearing at an output terminal of the diagnostic circuit. The diagnostic voltage may be a voltage that reflects the respective states of the three-phase motor and the motor driver circuit connected, directly or indirectly, to the diagnostic circuit.

In operation 830, the processor of the diagnostic module may determine whether coils of the three-phase motor are normal based on the diagnostic voltage.

According to an embodiment, the voltage of the output terminal that appears when the three-phase motor and the motor driver circuit are not damaged may be preset as a normal diagnostic voltage. The processor of the diagnostic module may determine that the coils of the three-phase motor are normal when the measured diagnostic voltage corresponds to the normal diagnostic voltage.

According to an embodiment, the voltage of the output terminal that appears when the three-phase motor is damaged and the motor driver circuit is not damaged may be preset as a first abnormal diagnostic voltage. The processor of the diagnostic module may determine that at least one of the coils of the three-phase motor is damaged when the measured diagnostic voltage corresponds to the first abnormal diagnostic voltage.

According to an embodiment, the voltage of the output terminal that appears when the motor driver circuit is damaged may be preset as a second abnormal diagnostic voltage. The processor of the diagnostic module may determine that the motor driver circuit is damaged when the measured diagnostic voltage corresponds to the second abnormal diagnostic voltage.

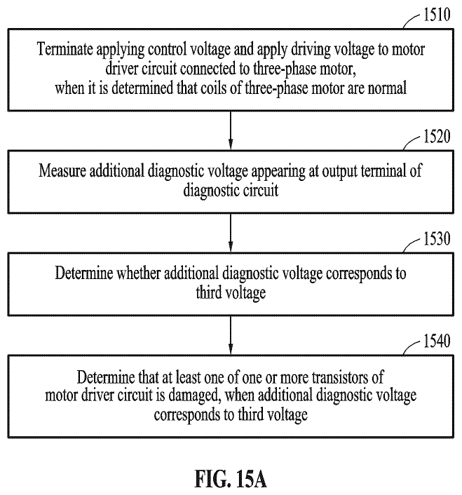

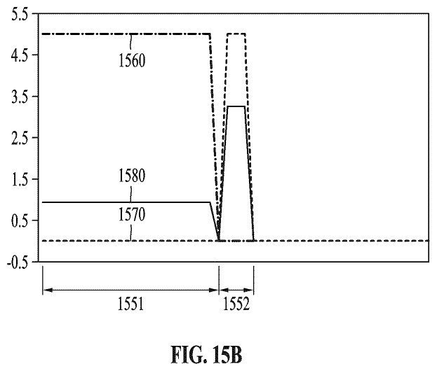

According to an embodiment, when it is determined that the three-phase motor and the motor driver circuit are normal, the processor may terminate applying the control voltage and apply the driving voltage to the motor driver circuit. When the driving voltage is applied to the motor driver circuit, the three-phase motor may be controlled by the motor driver circuit based on PWM. A method of determining whether the three-phase motor or the motor driver circuit is normal based on the diagnostic voltage measured after the driving voltage is applied to the motor driver circuit is described in detail with reference to FIGS. 15A to 19.

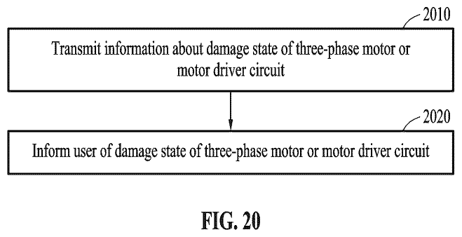

According to an embodiment, when it is determined that the three-phase motor or the motor driver circuit is damaged, the processor may notify a user of the damaged state of the three-phase motor or the motor driver circuit. The method of notifying the user of the damaged state of the three-phase motor or the motor driver circuit is described in detail below with reference to FIG. 20.

FIG. 9 illustrates a motor driver circuit, according to an embodiment.

According to an embodiment, a three-phase motor 900 (e.g., the motor 534 of FIG. 5A) may include a U-phase coil 902, a V-phase coil 904, and a W-phase coil 906.

According to an embodiment, a motor driver circuit 910 (e.g., the motor driver circuit 532 of FIG. 5A) may include a switch 911, a first transistor 912, a second transistor 913, a third transistor 914, a fourth transistor 915, a fifth transistor 916, and a sixth transistor 917. Each of the first transistor 912, the second transistor 913, and the third transistor 914 may be a top transistor of the motor driver circuit 910. Each of the fourth transistor 915, the fifth transistor 916, and the sixth transistor 917 may be a bottom transistor of the motor driver circuit 910.

The switch 911 may be used to control a driving voltage applied to the motor driver circuit 910. The driving voltage may be generated by a driving power source 920. For example, the driving power source 920 may be a system power source or a battery.

A source terminal of the first transistor 912 may be connected, directly or indirectly, to the U-phase coil 902 of the three-phase motor 900. A drain terminal of the fourth transistor 915 may be connected, directly or indirectly, to the U-phase coil 902 of the three-phase motor 900. A source terminal of the second transistor 913 may be connected, directly or indirectly, to the V-phase coil 904 of the three-phase motor 900. A drain terminal of the fifth transistor 916 may be connected, directly or indirectly, to the V-phase coil 904 of the three-phase motor 900. A source terminal of the third transistor 914 may be connected, directly or indirectly, to the W-phase coil 906 of the three-phase motor 900. A drain terminal of the sixth transistor 917 may be connected, directly or indirectly, to the W-phase coil 906 of the three-phase motor 900.

According to an embodiment, a processor (e.g., the processor 512 of FIG. 5A) of a control module (e.g., the control module 130 of FIG. 1 or the control module 510 of FIG. 5A) of a wearable device (e.g., the wearable device 100 of FIG. 1) may control the operation of the first transistor 912, the second transistor 913, the third transistor 914, the fourth transistor 915, the fifth transistor 916, and the sixth transistor 917 so that the motor may be controlled based on PWM. For example, the processor may control a gate voltage of each of the first transistor 912, the second transistor 913, the third transistor 914, the fourth transistor 915, the fifth transistor 916, and the sixth transistor 917 for PWM.

FIG. 10 illustrates a diagnostic circuit, according to an embodiment.

According to an embodiment, a diagnostic circuit 1000 (e.g., the diagnostic circuit 560 of FIG. 5A) may be electrically connected to the three-phase motor 900 (e.g., the motor 534 of FIG. 5A) described above with reference to FIG. 9. For example, the diagnostic circuit 1000 may be connected to each of the U-phase coil 902, the V-phase coil 904, and the W-phase coil 906 of the three-phase motor 900.

According to an embodiment, the diagnostic circuit 1000 may be electrically connected to the motor driver circuit 910 described above with reference to FIG. 9 through a terminal of the U-phase coil 902, a terminal of the V-phase coil 904, and a terminal of the W-phase coil 906 of the three-phase motor 900.

Hereinafter, the U-phase coil 902 may be referred to as a first coil, the V-phase coil 904 may be referred to as a second coil, and the W-phase coil 906 may be referred to as a third coil.

The diagnostic circuit 1000 may include a first terminal resistor 1001 connected to a first terminal connected to the first coil of the three-phase motor 900, a second terminal resistor 1002 connected to a second terminal connected to the second coil of the three-phase motor 900, and a third terminal resistor 1003 connected to a third terminal connected to the third coil of the three-phase motor 900. The third terminal resistor 1003 may be connected to an output terminal 1012.

The diagnostic circuit 1000 may include a first resistor 1004 positioned between the first terminal resistor 1001 and an input terminal 1011.

The diagnostic circuit 1000 may include a first transistor 1008 having a drain terminal connected to the first terminal resistor 1001 and the first resistor 1004, a source terminal connected to a second resistor 1005, and a gate terminal connected to the input terminal 1011. The first transistor 1008 may be an n-field-effect transistor (n-FET).

The diagnostic circuit 1000 may include the second resistor 1005 positioned between the source terminal of the first transistor 1008 and the second terminal resistor 1002.

The diagnostic circuit 1000 may include a second transistor 1009 having a drain terminal connected to the second terminal resistor 1002 and the second resistor 1005, a source terminal connected to a third resistor 1006, and a gate terminal connected to the input terminal 1011. The second transistor 1009 may be an n-FET.

The diagnostic circuit 1000 may include the third resistor 1006 positioned between the third terminal resistor 1003 and the source terminal of the second transistor 1009.

The diagnostic circuit 1000 may include a fourth resistor 1007 having a first terminal connected to the terminal resistor 1003 and the third resistor 1006, and a second terminal connected to the ground. The first terminal of the fourth resistor 1007 may be connected to the output terminal 1012.

The diagnostic circuit 1000 may include a pull-down resistor 1010 having a first terminal connected to the input terminal 1011, the gate terminal of the first transistor 1008, and the gate terminal of the second transistor 1009, and a second terminal connected to the ground.

According to an embodiment, a processor (e.g., the processor 512 of FIG. 5A) of the diagnostic module may output a control signal to apply a control voltage to the input terminal 1011. For example, the processor may apply the control voltage to the input terminal 1011 of the diagnostic circuit by outputting the control signal to a GPIO port of the processor. The processor may apply 0 V to the gate terminal of the first transistor 1008 and the gate terminal of the second transistor 1009 through the pull-down resistor before outputting the control signal to the input terminal 1011.

According to an embodiment, the processor of the diagnostic module may measure the voltage appearing at the output terminal 1012 as a diagnostic voltage.

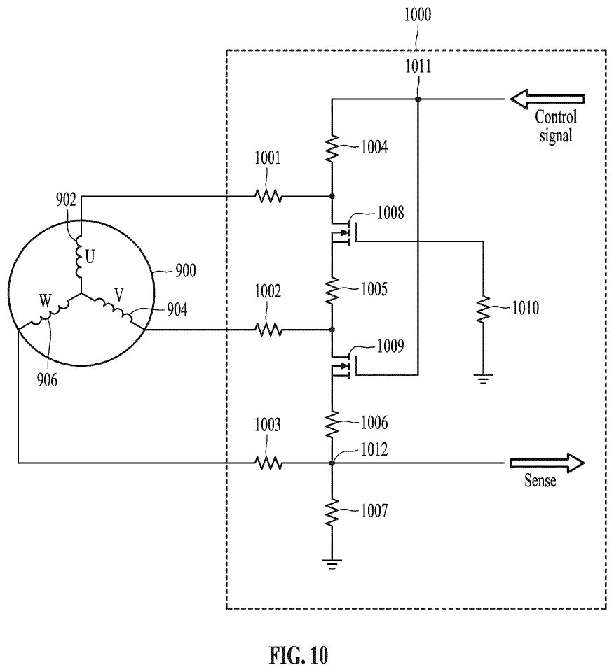

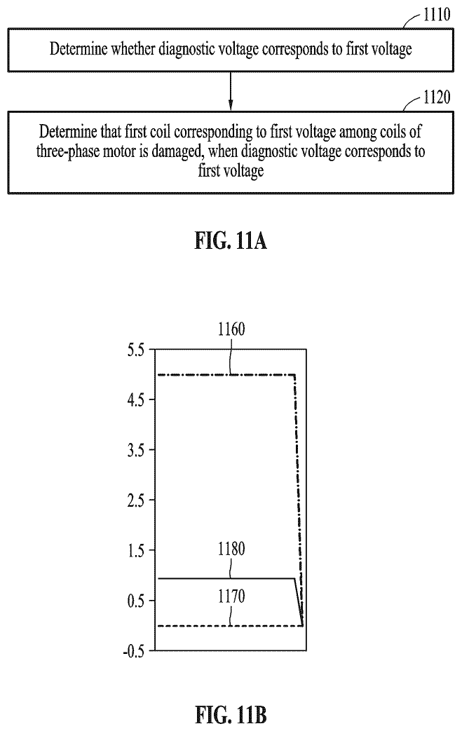

FIG. 11A is a flowchart of a method of determining whether coils of a three-phase motor are damaged, according to an embodiment.

According to an embodiment, operations 1110 and 1120 below may be relevant to operation 830 described above with reference to FIG. 8. For example, operation 830 may include operations 1110 and 1120.

According to an embodiment, operations 1110 and 1120 below may be performed by a diagnostic module of a wearable device (e.g., the wearable device 100 of FIG. 1). For example, operations 1110 and 1120 may be performed by a processor (e.g., the processor 512 of FIG. 5A) of the diagnostic module.

In operation 1110, the processor(s) of the diagnostic module may determine whether a diagnostic voltage corresponds to a first voltage.

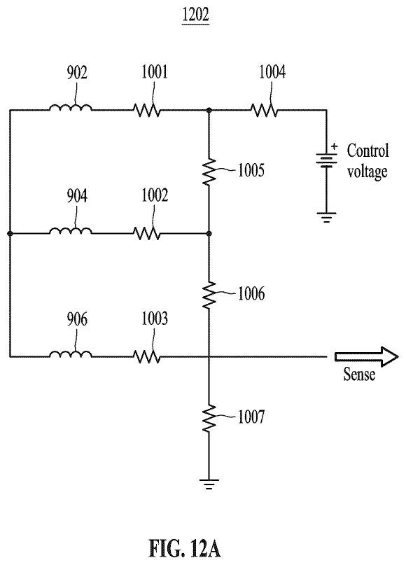

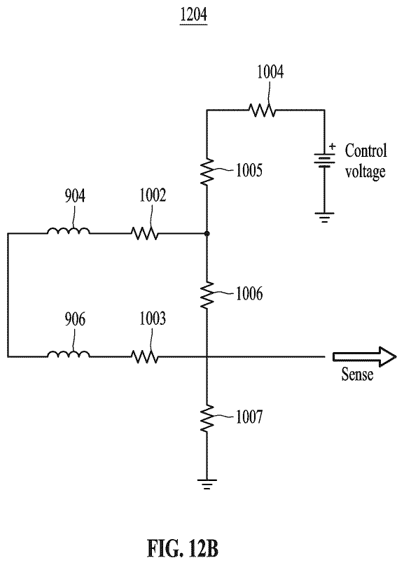

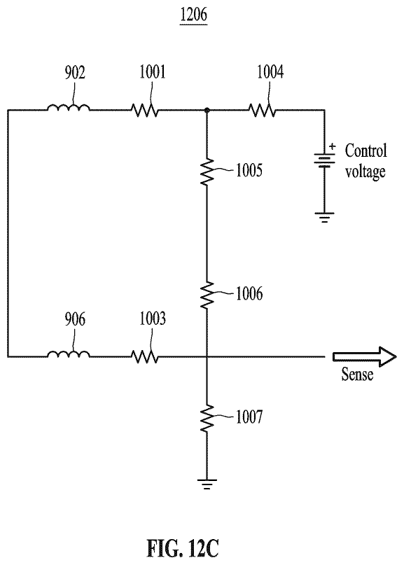

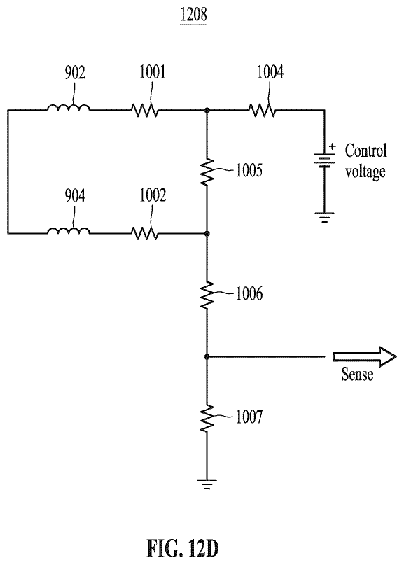

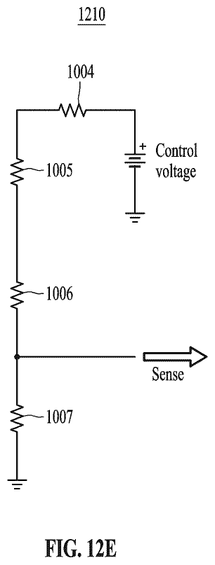

According to an embodiment, the processor may determine whether the diagnostic voltage, as the first voltage, corresponds to a normal diagnostic voltage that appears when a motor driver circuit (e.g., the motor driver circuit 532 of FIG. 5A or the motor driver circuit 910 of FIG. 9) of a three-phase motor (e.g., the motor 534 of FIG. 5A or the three-phase motor 900 of FIG. 9) is not damaged. An equivalent circuit of the three-phase motor, the motor driver circuit, and a diagnostic circuit (e.g., the diagnostic circuit 560 of FIG. 5A or the diagnostic circuit 1000 of FIG. 10) when the three-phase motor and the motor driver circuit are not damaged is illustrated with reference to FIG. 12A.

According to an embodiment, the processor may determine whether the diagnostic voltage, as the first voltage, corresponds to a first abnormal diagnostic voltage that appears when the three-phase motor is damaged and the motor driver circuit is not damaged. For example, the processor may determine whether the diagnostic voltage corresponds to a U-phase coil damage voltage that appears when a U-phase coil (e.g., the U-phase coil 902 of FIG. 9) of the three-phase motor is damaged. For example, the processor may determine whether the diagnostic voltage corresponds to a V-phase coil damage voltage that appears when a V-phase coil (e.g., the V-phase coil 904 of FIG. 9) of the three-phase motor is damaged. For example, the processor may determine whether the diagnostic voltage corresponds to a V-phase coil damage voltage that appears when a W-phase coil (e.g., the W-phase coil 906 of FIG. 9) of the three-phase motor is damaged. Equivalent circuits of the three-phase motor, the motor driver circuit, and the diagnostic circuit when the three-phase motor is damaged and the motor driver circuit is not damaged are shown with reference to FIGS. 12B, 12C, 12D, and 12E.

In operation 1120, the processor of the diagnostic module may determine that a first coil (or target coil) (e.g., the U-phase coil, the V-phase coil, or the W-phase coil) corresponding to the first voltage (e.g., the U-phase coil damage voltage, the V-phase coil damage voltage, or the W-phase coil damage voltage) among the coils of the three-phase motor is damaged, when the diagnostic voltage corresponds to the first voltage.

FIG. 11B illustrates a control voltage, a driving voltage, and a diagnostic voltage, according to an embodiment.

According to an embodiment, a processor (e.g., the processor 512 of FIG. 5A) of a diagnostic module of a wearable device (e.g., the wearable device 100 of FIG. 1) may apply a control voltage 1160 to an input terminal (e.g., the input terminal 1011 of FIG. 10) of a diagnostic circuit (e.g., the diagnostic circuit 560 of FIG. 5A or the diagnostic circuit 1000 of FIG. 10) by outputting a control signal to a GPIO port of the processor. For example, the control voltage may be 5V and is not limited to the described embodiment.

According to an embodiment, the processor may apply the control voltage to the input terminal of the diagnostic circuit while a driving voltage 1170 is not applied to a three-phase motor (e.g., the motor 534 of FIG. 5A or the three-phase motor 900 of FIG. 9). The driving voltage may be a voltage applied to a motor driver circuit (e.g., the motor driver circuit 532 of FIG. 5A or the motor driver circuit 910 of FIG. 9) by a driving power source (e.g., the driving power source 920 of FIG. 9).

According to an embodiment, the processor may measure the voltage appearing at an output terminal (e.g., the output terminal 1012 of FIG. 10) of the diagnostic circuit as a diagnostic voltage 1180. It is exemplarily shown that the diagnostic voltage 1180 corresponds to a normal diagnostic voltage that appears when the three-phase motor and the motor driver circuit are normal, but the diagnostic voltage 1180 may appear differently depending on whether the three-phase motor is damaged and whether the motor driver circuit is damaged.

According to an embodiment, resistance elements with different resistance values may be used in the diagnostic circuit so that the measured diagnostic voltage may appear differently depending on the damage to each coil of the three-phase motor and each bottom transistor of the damaged motor driver circuit.

FIG. 12A is an equivalent circuit of a three-phase motor, a motor driver circuit, and a diagnostic circuit when coils of the three-phase motor and transistors of the motor driver circuit are all normal, according to an embodiment.

According to an embodiment, an equivalent circuit 1202 of the three-phase motor 900, the motor driver circuit 910, and the diagnostic circuit 1000 described with reference to FIG. 10, when the U-phase coil 902, the V-phase coil 904, and the W-phase coil 906 of the three-phase motor 900 and the transistors 912 to 917 of the motor driver circuit 910 described above with reference to FIG. 9 are all normal, is shown.

For example, the resistance value of the first terminal resistor 1001 may be 1 kiloohm (kΩ), the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor may be 2.37 k Ω, and the control voltage may be 5 V. In the above example, the diagnostic voltage of the equivalent circuit 1202 may be 0.942 V.

FIG. 12B is an equivalent circuit of a three-phase motor, a motor driver circuit, and a diagnostic circuit when a U-phase coil of the three-phase motor is damaged, according to an embodiment.

According to an embodiment, an equivalent circuit 1204 for a case where the U-phase coil 902 of the three-phase motor 900 is damaged in the equivalent circuit 1202 described above with reference to FIG. 12A is shown.

For example, the resistance value of the first terminal resistor 1001 may be 1 kΩ, the resistance value of the second terminal resistor may be 1.5 k Ω, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the control voltage may be 5 V. In the above example, the diagnostic voltage of the equivalent circuit 1204 may be 0.495 V.

FIG. 12C is an equivalent circuit of a three-phase motor, a motor driver circuit, and a diagnostic circuit when a V-phase coil of the three-phase motor is damaged, according to an embodiment.

According to an embodiment, an equivalent circuit 1206 for a case where the V-phase coil 904 of the three-phase motor 900 is damaged in the equivalent circuit 1202 described above with reference to FIG. 12A is shown.

For example, the resistance value of the first terminal resistor 1001 may be 1 kΩ, the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the control voltage may be 5 V. In the above example, the diagnostic voltage of the equivalent circuit 1206 may be 0.799 V.

FIG. 12D is an equivalent circuit of a three-phase motor, a motor driver circuit, and a diagnostic circuit when a W-phase coil of the three-phase motor is damaged, according to an embodiment.

According to an embodiment, an equivalent circuit 1208 for a case where the W-phase coil 906 of the three-phase motor 900 is damaged in the equivalent circuit 1202 described above with reference to FIG. 12A is shown.

For example, the resistance value of the first terminal resistor 1001 may be 1 kΩ, the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the control voltage may be 5 V. In the above example, the diagnostic voltage of the equivalent circuit 1208 may be 0.606 V.

FIG. 12E is an equivalent circuit of a three-phase motor, a motor driver circuit, and a diagnostic circuit when a plurality of coils of the three-phase motor are damaged, according to an embodiment.

According to an embodiment, an equivalent circuit 1210 for a case where two or more coils of the three-phase motor 900 are damaged in the equivalent circuit 1202 described above with reference to FIG. 12A is shown.

For example, the resistance value of the first terminal resistor 1001 may be 1 kΩ, the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the control voltage may be 5 V. In the above example, the diagnostic voltage of the equivalent circuit 1210 may be 0.397 V.

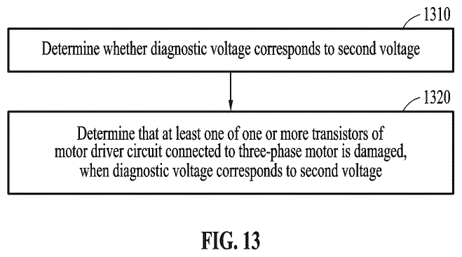

FIG. 13 is a flowchart of a method of determining whether a bottom transistor of a motor driver circuit is damaged, according to an embodiment.

According to an embodiment, operations 1310 and 1320 below may be relevant to operation 830 described above with reference to FIG. 8. For example, operation 830 may include operations 1310 and 1320.

According to an embodiment, operations 1310 and 1320 below may be performed by a diagnostic module of a wearable device (e.g., the wearable device 100 of FIG. 1). For example, operations 1310 and 1320 may be performed by a processor (e.g., the processor 512 of FIG. 5A) of the diagnostic module.

In operation 1310, the processor of the diagnostic module may determine whether a diagnostic voltage corresponds to a second voltage.

According to an embodiment, the processor may determine whether the diagnostic voltage, as the second voltage, corresponds to a second abnormal diagnostic voltage that appears when a motor driver circuit (e.g., the motor driver circuit 532 of FIG. 5A or the motor driver circuit 910 of FIG. 9) is damaged. For example, when a bottom transistor of the motor driver circuit is damaged, the diagnostic voltage may correspond to the second abnormal diagnostic voltage.

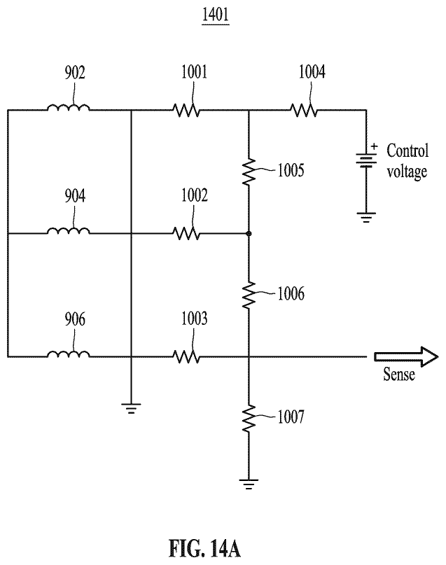

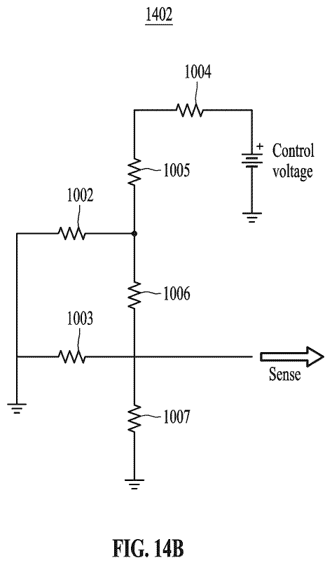

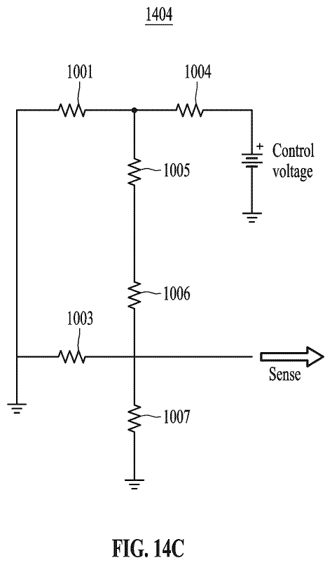

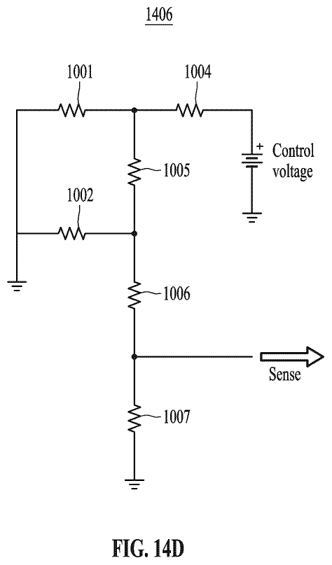

For example, the processor may determine whether the diagnostic voltage corresponds to a bottom transistor damage voltage that appears when a fourth transistor (e.g., the fourth transistor 915 of FIG. 9), a fifth transistor (e.g., the fifth transistor 916 of FIG. 9), or a sixth transistor (e.g., the sixth transistor 917 of FIG. 9) of the motor driver circuit is damaged. An equivalent circuit of the three-phase motor, the motor driver circuit, and the diagnostic circuit when a bottom transistor of the motor driver circuit is damaged is shown in FIG. 14A.

According to an embodiment, the processor may determine whether the diagnostic voltage, as the second voltage, corresponds to an additional bottom transistor damage voltage that appears when a bottom transistor of the motor driver circuit and a coil (e.g., the U-phase coil 902, the V-phase coil 904, or the W-phase coil 906) of the three-phase motor (e.g., the motor 534 of FIG. 5A or the three-phase motor 900 of FIG. 9) are damaged. For example, when a bottom transistor of the motor driver circuit and a coil of the three-phase motor are damaged at the same time, the diagnostic voltage may correspond to the second abnormal diagnostic voltage (e.g., the additional bottom transistor damage voltage). Equivalent circuits of the three-phase motor, the motor driver circuit, and the diagnostic circuit when a bottom transistor of the motor driver circuit and a coil of the three-phase motor are damaged at the same time are shown with reference to FIGS. 14B, 14C, and 14D.

In operation 1320, the processor of the diagnostic module may determine that at least one bottom transistor among one or more transistors of the motor driver circuit is damaged when the diagnostic voltage corresponds to the second voltage (e.g., the bottom transistor damage voltage).

According to an embodiment, the processor(s) of the diagnostic module may determine that at least one bottom transistor among the one or more transistors of the motor driver circuit and a coil of the three-phase motor are damaged at the same time when the diagnostic voltage corresponds to the second voltage (e.g., the additional bottom transistor damage voltage).

FIG. 14A is an equivalent circuit of a three-phase motor, a motor driver circuit, and a diagnostic circuit when a bottom transistor of the motor driver circuit is damaged, according to an embodiment.

According to an embodiment, an equivalent circuit 1401 of the three-phase motor 900, the motor driver circuit 910, and the diagnostic circuit 1000 described with reference to FIG. 10, for a case where a bottom transistor (e.g., the fourth transistor 915, the fifth transistor 916, or the sixth transistor 917) among the transistors 912 to 917 of the motor driver circuit 910 described above with reference to FIG. 9 is damaged, is shown.

For example, the resistance value of the first terminal resistor 1001 may be 1 kΩ, the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the control voltage may be 5 V. In the above example, the diagnostic voltage of the equivalent circuit 1401 may be 0.056 V.

FIG. 14B is an equivalent circuit of a three-phase motor, a motor driver circuit, and a diagnostic circuit when a U-phase coil of the three-phase motor and a bottom transistor of the motor driver circuit are damaged, according to an embodiment.

According to an embodiment, an equivalent circuit 1402 of the three-phase motor 900, the motor driver circuit 910, and the diagnostic circuit 1000 described with reference to FIG. 10, for a case where the U-phase coil 902 of the three-phase motor 900 and a bottom transistor (e.g., the fourth transistor 915, the fifth transistor 916, or the sixth transistor 917) among the transistors 912 to 917 of the motor driver circuit 910 described above with reference to FIG. 9 are damaged at the same time, is shown.

For example, the resistance value of the first terminal resistor 1001 may be 1 kΩ, the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the control voltage may be 5 V. In the above example, the diagnostic voltage of the equivalent circuit 1402 may be 0.0619 V.

FIG. 14C is an equivalent circuit of a three-phase motor, a motor driver circuit, and a diagnostic circuit when a V-phase coil of the three-phase motor and a bottom transistor of the motor driver circuit are damaged, according to an embodiment.

According to an embodiment, an equivalent circuit 1404 of the three-phase motor 900, the motor driver circuit 910, and the diagnostic circuit 1000 described with reference to FIG. 10, for a case where the V-phase coil 904 of the three-phase motor 900 and a bottom transistor (e.g., the fourth transistor 915, the fifth transistor 916, or the sixth transistor 917) among the transistors 912 to 917 of the motor driver circuit 910 described above with reference to FIG. 9 are damaged at the same time, is shown.

For example, the resistance value of the first terminal resistor 1001 may be 1 kΩ, the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the control voltage may be 5 V. In the above example, the diagnostic voltage of the equivalent circuit 1404 may be 0.3275 V.

FIG. 14D is an equivalent circuit of a three-phase motor, a motor driver circuit, and a diagnostic circuit when a W-phase coil of the three-phase motor and a bottom transistor of the motor driver circuit are damaged, according to an embodiment.

According to an embodiment, an equivalent circuit 1406 of the three-phase motor 900, the motor driver circuit 910, and the diagnostic circuit 1000 described with reference to FIG. 10, for a case where the W-phase coil 906 of the three-phase motor 900 and a bottom transistor (e.g., the fourth transistor 915, the fifth transistor 916, or the sixth transistor 917) among the transistors 912 to 917 of the motor driver circuit 910 described above with reference to FIG. 9 are damaged at the same time, is shown.

For example, the resistance value of the first terminal resistor 1001 may be 1 kΩ, the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the control voltage may be 5 V. In the above example, the diagnostic voltage of the equivalent circuit 1406 may be 0.0617 V.

FIG. 15A is a flowchart of a method of determining whether a top transistor of a motor driver circuit is damaged, according to an embodiment.

According to an embodiment, operations 1510 to 1540 below may be performed by a diagnostic module of a wearable device (e.g., the wearable device 100 of FIG. 1). For example, operations 1510 to 1540 may be performed by a processor(s) (e.g., the processor 512 of FIG. 5A) of the diagnostic module.

According to an embodiment, operations 1510 to 1540 may be performed after operation 830 described above with reference to FIG. 8 is performed. For example, when it is determined that coils (e.g., the U-phase coil 902, the V-phase coil 904, and the W-phase coil 906) of a three-phase motor (e.g., the motor 534 of FIG. 5A) or the three-phase motor 900 of FIG. 9) are normal and bottom transistors of a motor driver circuit (e.g., the motor driver circuit 532 of FIG. 5A or the motor driver circuit 910 of FIG. 9) are normal, operation 1510 may be performed.

In operation 1510, when it is determined that the coils of the three-phase motor are normal, the processor of the diagnostic module may terminate applying a control voltage and apply a driving voltage to the motor driver circuit connected to the three-phase motor. The driving voltage may be a voltage applied to the motor driver circuit by a driving power source (e.g., the driving power source 920 of FIG. 9). For example, the processor may connect the driving power source 920 and the motor driver circuit 910 using the switch 911 of the motor driver circuit 910 to apply the driving voltage to the motor driver circuit 910.

In operation 1520, the processor of the diagnostic module may measure an additional diagnostic voltage that appears at an output terminal (e.g., the output terminal 1012 of FIG. 10) of a diagnostic circuit (e.g., the diagnostic circuit 560 of FIG. 5A or the diagnostic circuit 1000 of FIG. 10). The processor of the diagnostic module may continuously measure the voltage appearing at the output terminal as a diagnostic voltage, and the term “additional diagnostic voltage” is used to be distinguished from the “diagnostic voltage” measured in operation 820 described above with reference to FIG. 8.

In operation 1530, the processor of the diagnostic module may determine whether the additional diagnostic voltage corresponds to a third voltage.

According to an embodiment, the processor may determine whether the additional diagnostic voltage, as the third voltage, corresponds to a third abnormal diagnostic voltage that appears when the motor driver circuit is damaged. For example, when a top transistor of the motor driver circuit is damaged, the additional diagnostic voltage may correspond to the third abnormal diagnostic voltage.

According to an embodiment, the processor may determine whether the additional diagnostic voltage, as the third voltage, corresponds to an additional third abnormal diagnostic voltage that appears when the motor driver circuit and a coil (e.g., the U-phase coil 902, the V-phase coil 904, or the W-phase coil 906) of the three-phase motor are damaged at the same time. For example, when a top transistor of the motor driver circuit and a coil of the three-phase motor are damaged at the same time, the additional diagnostic voltage may correspond to the additional third abnormal diagnostic voltage. For example, although the coil of the three-phase motor has not been damaged until operation 830 described above with reference to FIG. 8 is performed, the coil of the three-phase motor may be damaged before operation 1520 is performed.

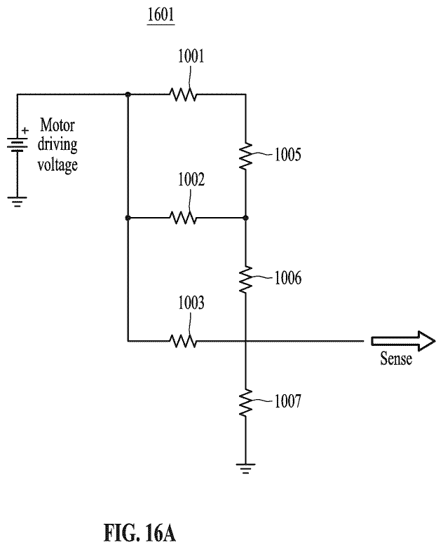

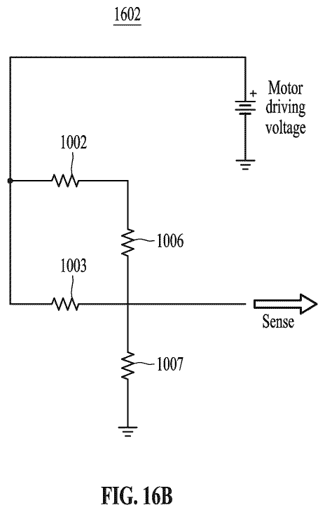

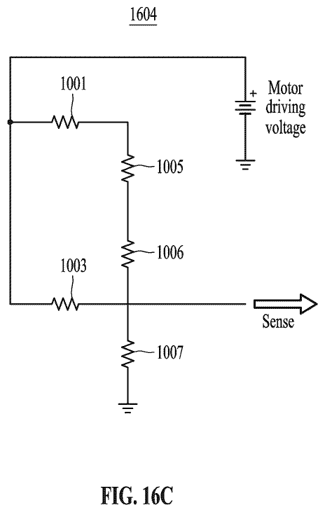

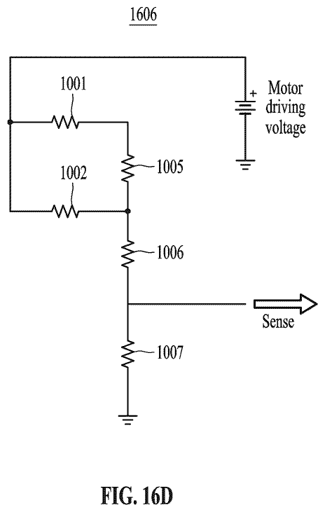

For example, the processor may determine whether the additional diagnostic voltage corresponds to a top transistor damage voltage that appears when a first transistor (e.g., the first transistor 912 of FIG. 9), a second transistor (e.g., the second transistor 913 of FIG. 9), or a third transistor (e.g., the third transistor 914 of FIG. 9) of the motor driver circuit is damaged. An equivalent circuit of the three-phase motor, the motor driver circuit, and the diagnostic circuit when a top transistor of the motor driver circuit is damaged is shown in FIG. 16A.

According to an embodiment, the processor may determine whether the diagnostic voltage, as the third voltage, corresponds to an additional top transistor damage voltage that appears when a top transistor of the motor driver circuit and a coil (e.g., the U-phase coil 902, the V-phase coil 904, or the W-phase coil 906) of the three-phase motor are damaged at the same time. For example, when a top transistor of the motor driver circuit and a coil of the three-phase motor are damaged at the same time, the diagnostic voltage may correspond to the third abnormal diagnostic voltage (e.g., the additional top transistor damage voltage). Equivalent circuits of the three-phase motor, the motor driver circuit, and the diagnostic circuit when a top transistor of the motor driver circuit and a coil of the three-phase motor are damaged at the same time are shown with reference to FIGS. 16B, 16C, and 16D.

In operation 1540, the processor of the diagnostic module may determine that at least one top transistor among one or more transistors of the motor driver circuit is damaged when the additional diagnostic voltage corresponds to the second voltage (e.g., the top transistor damage voltage).

According to an embodiment, the processor of the diagnostic module may determine that at least one top transistor among the one or more transistors of the motor driver circuit and a coil of the three-phase motor are damaged at the same time when the diagnostic voltage corresponds to the third voltage (e.g., the additional top transistor damage voltage).

FIG. 15B illustrates a control voltage, a driving voltage, and a diagnostic voltage, according to an embodiment.

According to an embodiment, in a first period 1551, a processor (e.g., the processor 512 of FIG. 5A) of a diagnostic module may apply a control voltage 1560 to an input terminal (e.g., the input terminal 1011 of FIG. 10) of a diagnostic circuit (e.g., the diagnostic circuit 560 of FIG. 5A or the diagnostic circuit 1000 of FIG. 10) by outputting a control signal to a GPIO port of the processor. For example, the control voltage may be 5V and is not limited to the described embodiment. The first period 1551 may correspond to the time during which operations 810 to 830 described above with reference to FIG. 8 are performed.

According to an embodiment, in the first period 1551, the processor of the diagnostic module may measure a voltage 1580 appearing at an output terminal (e.g., the output terminal 1012 of FIG. 10) of the diagnostic circuit as a diagnostic voltage.

According to an embodiment, in a second period 1552, the processor of the diagnostic module may terminate applying the control voltage 1560 and apply a driving voltage 1570 to a motor driver circuit (e.g., the motor driver circuit 532 of FIG. 5A or the motor driver circuit 910 of FIG. 9). For example, the driving voltage 1570 applied in the second period 1552 may be 5 V, and is not limited to the described embodiment.

According to an embodiment, in the second period 1552, the processor of the diagnostic module may measure the voltage 1580 appearing at the output terminal of the diagnostic circuit as an additional diagnostic voltage.

According to an embodiment, the processor may determine whether the additional diagnostic voltage, as the third voltage, corresponds to a third abnormal diagnostic voltage that appears when the motor driver circuit is damaged. For example, when a top transistor of the motor driver circuit is damaged, the additional diagnostic voltage may correspond to the third abnormal diagnostic voltage.

According to an embodiment, when the additional diagnostic voltage corresponds to the third voltage, the processor may determine that at least one of the one or more transistors of the motor driver circuit is damaged.

FIG. 16A is an equivalent circuit of a three-phase motor, a motor driver circuit, and a diagnostic circuit when a top transistor of the motor driver circuit is damaged, according to an embodiment.

According to an embodiment, an equivalent circuit 1601 of the three-phase motor 900, the motor driver circuit 910, and the diagnostic circuit 1000 described with reference to FIG. 10, for a case where the U-phase coil 902, the V-phase coil 904, and the W-phase coil 906 of the three-phase motor 900 and a top transistor (e.g., the first transistor 912, the second transistor 913, or the third transistor 914) among the transistors 912 to 917 of the motor driver circuit 910 are damaged, is shown. The equivalent circuit 1601 is a circuit that is shown when a control voltage is not applied to the diagnostic circuit 1000 and a driving voltage is applied to the motor driver circuit 910.

For example, the resistance value of the first terminal resistor 1001 may be 1 kΩ, the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the driving voltage may be 5 V. In the example above, the additional diagnostic voltage of the equivalent circuit 1601 may be 3.253 V.

FIG. 16B is an equivalent circuit of a three-phase motor, a motor driver circuit, and a diagnostic circuit when a U-phase coil of the three-phase motor and a top transistor of the motor driver circuit are damaged, according to an embodiment.

According to an embodiment, an equivalent circuit 1602 of the three-phase motor 900, the motor driver circuit 910, and the diagnostic circuit 1000 described with reference to FIG. 10, for a case where the U-phase coil 902 of the three-phase motor 900 and a top transistor (e.g., the first transistor 912, the second transistor 913, or the third transistor 914) among the transistors 912 to 917 of the motor driver circuit 910 described above with reference to FIG. 9 are damaged at the same time, is shown. The equivalent circuit 1602 is a circuit that is shown when a control voltage is not applied to the diagnostic circuit 1000 and a driving voltage is applied to the motor driver circuit 910.

For example, the resistance value of the first terminal resistor 1001 may be 1 kΩ, the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the driving voltage may be 5 V. In the above example, the additional diagnostic voltage of the equivalent circuit 1602 may be 3.24 V.

FIG. 16C is an equivalent circuit of a three-phase motor, a motor driver circuit, and a diagnostic circuit when a V-phase coil of the three-phase motor and a top transistor of the motor driver circuit are damaged according to an embodiment.

According to an embodiment, an equivalent circuit 1604 of the three-phase motor 900, the motor driver circuit 910, and the diagnostic circuit 1000 described with reference to FIG. 10, for a case where the V-phase coil 904 of the three-phase motor 900 and a top transistor (e.g., the first transistor 912, the second transistor 913, or the third transistor 914) among the transistors 912 to 917 of the motor driver circuit 910 described above with reference to FIG. 9 are damaged at the same time, is shown. The equivalent circuit 1604 is a circuit that is shown when a control voltage is not applied to the diagnostic circuit 1000 and a driving voltage is applied to the motor driver circuit 910.

For example, the resistance value of the first terminal resistor 1001 may be 1 kΩ, the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the driving voltage may be 5 V. In the above example, the additional diagnostic voltage of the equivalent circuit 1604 may be 2.6 V.

FIG. 16D is an equivalent circuit of a three-phase motor, a motor driver circuit, and a diagnostic circuit when a W-phase coil of the three-phase motor and a top transistor of the motor driver circuit are damaged, according to an embodiment.

According to an embodiment, an equivalent circuit 1606 of the three-phase motor 900, the motor driver circuit 910, and the diagnostic circuit 1000 described with reference to FIG. 10, for a case where the W-phase coil 906 of the three-phase motor 900 and a top transistor (e.g., the first transistor 912, the second transistor 913, or the third transistor 914) among the transistors 912 to 917 of the motor driver circuit 910 described above with reference to FIG. 9 are damaged at the same time, is shown. The equivalent circuit 1606 is a circuit that is shown when a control voltage is not applied to the diagnostic circuit 1000 and a driving voltage is applied to the motor driver circuit 910.

For example, the resistance value of the first terminal resistor 1001 may be 1 kΩ, the resistance value of the second terminal resistor may be 1.5 kΩ, the resistance value of the third terminal resistor 1003 may be 21.5 kΩ, the resistance value of the first resistance 1004 may be 100 Ω, the resistance value of the second resistor 1005 may be 12.4 kΩ, the resistance value of the third resistor 1006 may be 15 kΩ, the resistance value of the fourth resistor 1007 may be 2.37 kΩ, and the driving voltage may be 5 V. In the above example, the additional diagnostic voltage of the equivalent circuit 1606 may be 2.03 V.

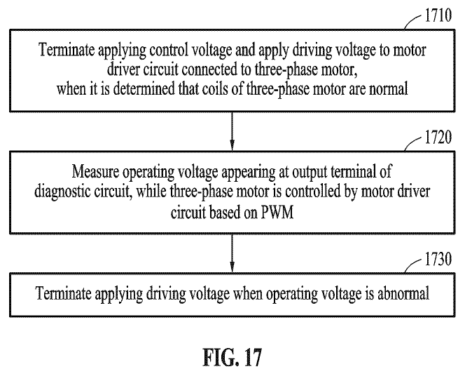

FIG. 17 is a flowchart of a method of monitoring the state of a three-phase motor while the three-phase motor is controlled by a motor driver circuit based on PWM, according to an embodiment.

According to an embodiment, operations 1710 to 1730 below may be performed by a diagnostic module of a wearable device (e.g., the wearable device 100 of FIG. 1). For example, operations 1710 to 1730 may be performed by a processor (e.g., the processor 512 of FIG. 5A) of the diagnostic module.

According to an embodiment, operations 1710 to 1730 may be performed after operation 830 described above with reference to FIG. 8 is performed. For example, when it is determined that coils (e.g., the U-phase coil 902, the V-phase coil 904, and the W-phase coil 906) of a three-phase motor (e.g., the motor 534 of FIG. 5A) or the three-phase motor 900 of FIG. 9) are normal and bottom transistors of a motor driver circuit (e.g., the motor driver circuit 532 of FIG. 5A or the motor driver circuit 910 of FIG. 9) are normal, operation 1510 may be performed.

In operation 1710, when it is determined that the coils of the three-phase motor are normal, the processor of the diagnostic module may terminate applying a control voltage and apply a driving voltage to the motor driver circuit connected to the three-phase motor. The description of operation 1510 described above with reference to FIG. 15A may be similarly applied to the description of operation 1710.

In operation 1720, the processor of the diagnostic module may measure an operating voltage that appears at an output terminal (e.g., the output terminal 1012 of FIG. 10) of a diagnostic circuit (e.g., the diagnostic circuit 560 of FIG. 5A or the diagnostic circuit 1000 of FIG. 10) while the three-phase motor is controlled by the motor driver circuit based on PWM. The processor of the diagnostic module may continuously measure the voltage appearing at the output terminal as a diagnostic voltage, and the term “operating voltage” is used to be distinguished from the “diagnostic voltage” measured in operation 820 described above with reference to FIG. 8 and the “additional diagnostic voltage” measured in operation 1520 described above with reference to FIG. 15A.

According to an embodiment, operation 1720 may be performed when it is determined that the transistors of the motor driver circuit are all normal, through operations 1520 to 1540 described above with reference to FIG. 15A. For example, when it is determined that the transistors of the motor driver circuit are all normal, the three-phase motor may be controlled by the motor driver circuit based on PWM.

In operation 1730, the processor of the diagnostic module may terminate applying the driving voltage when the operating voltage is abnormal. For example, the processor of the diagnostic module may calculate a reference operating voltage which is normal for an equivalent circuit of the motor driver circuit that changes based on PWM, and determine whether the operating voltage appearing at the output terminal corresponds to the reference operating voltage. The processor may determine that the operating voltage is abnormal when the operating voltage does not correspond to the reference operating voltage.

According to an embodiment, after operation 1730 is performed, operations 810 to 830 described above with reference to FIG. 8 may be re-performed. Additionally, when it is determined that the coils of the three-phase motor are normal through operations 810 to 830 re-performed, operations 1510 to 1540 described above with reference to FIG. 15A may be re-performed.

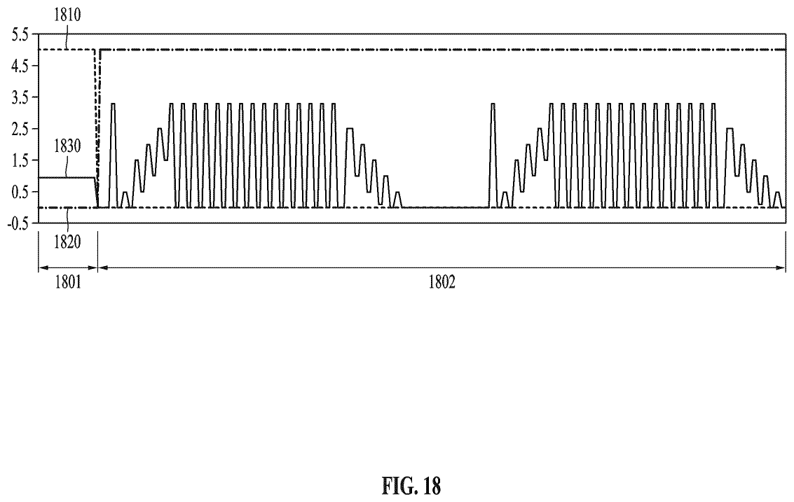

FIG. 18 illustrates a control voltage, a driving voltage, and a diagnostic voltage that appear while a three-phase motor and a motor driver circuit operate normally, according to an embodiment.

According to an embodiment, in a first period 1801, a processor (e.g., the processor 512 of FIG. 5A) of a diagnostic module may apply a control voltage 1810 to an input terminal (e.g., the input terminal 1011 of FIG. 10) of a diagnostic circuit (e.g., the diagnostic circuit 560 of FIG. 5A or the diagnostic circuit 1000 of FIG. 10) by outputting a control signal to a GPIO port of the processor. For example, the control voltage may be 5V and is not limited to the described embodiment. The first period 1801 may correspond to the time during which operations 810 to 830 described above with reference to FIG. 8 are performed.

According to an embodiment, in the first period 1801, the processor of the diagnostic module may measure a voltage 1830 appearing at an output terminal (e.g., the output terminal 1012 of FIG. 10) of the diagnostic circuit as a diagnostic voltage.

According to an embodiment, in a second period 1802, the processor of the diagnostic module may terminate applying the control voltage 1810 and apply a driving voltage 1820 to a motor driver circuit (e.g., the motor driver circuit 532 of FIG. 5A or the motor driver circuit 910 of FIG. 9). For example, the driving voltage 1820 applied in the second period 1802 may be 5 V, and is not limited to the described embodiment.

According to an embodiment, in the second period 1802, the processor of the diagnostic module may measure the voltage 1830 appearing at the output terminal of the diagnostic circuit as an operating voltage. For example, the processor of the diagnostic module may calculate a reference operating voltage which is normal for an equivalent circuit of the motor driver circuit that changes based on PWM, and determine whether the operating voltage appearing at the output terminal corresponds to the reference operating voltage. The processor may determine that the operating voltage is normal when the operating voltage corresponds to the reference operating voltage.

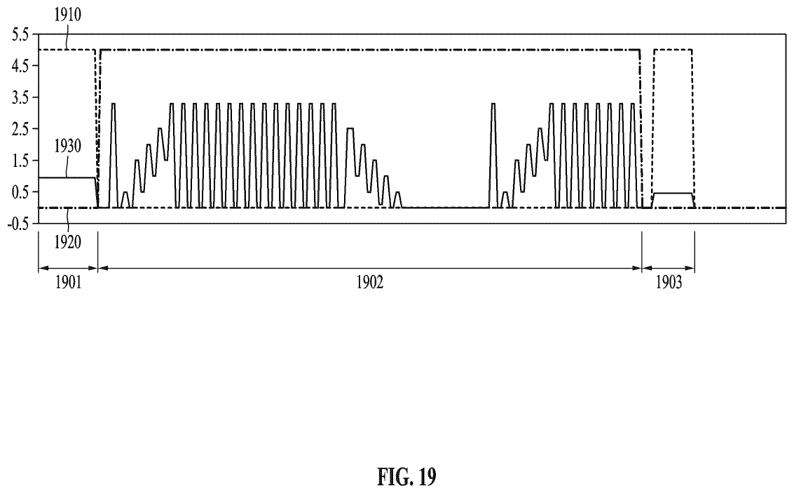

FIG. 19 illustrates a control voltage, a driving voltage, and a diagnostic voltage that appear while a three-phase motor or a motor driver circuit operates abnormally, according to an embodiment.

According to an embodiment, in a first period 1901, a processor (e.g., the processor 512 of FIG. 5A) of a diagnostic module may apply a control voltage 1910 to an input terminal (e.g., the input terminal 1011 of FIG. 10) of a diagnostic circuit (e.g., the diagnostic circuit 560 of FIG. 5A or the diagnostic circuit 1000 of FIG. 10) by outputting a control signal to a GPIO port of the processor. For example, the control voltage may be 5V and is not limited to the described embodiment. The first period 1901 may correspond to the time during which operations 810 to 830 described above with reference to FIG. 8 are performed.

According to an embodiment, in the first period 1901, the processor of the diagnostic module may measure a voltage 1930 appearing at an output terminal (e.g., the output terminal 1012 of FIG. 10) of the diagnostic circuit as a diagnostic voltage.

According to an embodiment, in a second period 1902, the processor of the diagnostic module may terminate applying the control voltage 1910 and apply a driving voltage 1920 to a motor driver circuit (e.g., the motor driver circuit 532 of FIG. 5A or the motor driver circuit 910 of FIG. 9). For example, the driving voltage 1920 applied in the second period 1902 may be 5 V, and is not limited to the described embodiment.

According to an embodiment, in the second period 1902, the processor of the diagnostic module may measure the voltage 1930 appearing at the output terminal of the diagnostic circuit as an operating voltage. For example, the processor of the diagnostic module may calculate a reference operating voltage which is normal for an equivalent circuit of the motor driver circuit that changes based on PWM, and determine whether the operating voltage appearing at the output terminal corresponds to the reference operating voltage. The processor may determine that the operating voltage is abnormal when the operating voltage does not correspond to the reference operating voltage. For example, although it is determined that the coils (e.g., the U-phase coil 902, the V-phase coil 904, and the W-phase coil 906) of a three-phase motor (e.g., the motor 534 of FIG. 5A or the three-phase motor 900 of FIG. 9) in the first period 1901, the operating voltage may not correspond to the reference operating voltage when at least one of the coils of the three-phase motor is damaged in the second period 1902.

According to an embodiment, when it is determined that the operating voltage is abnormal, the processor of the diagnostic module may stop controlling the three-phase motor based on PWM and terminate applying the driving voltage 1920.

According to an embodiment, in a third period 1903, the processor of the diagnostic module may apply the control voltage 1910 to the diagnostic circuit. The processor of the diagnostic module may measure the voltage 1930 appearing at the output terminal of the diagnostic circuit as a diagnostic voltage.

The processor of the diagnostic module may determine a damaged coil of the three-phase motor or a damaged transistor of the motor driver circuit based on whether the diagnostic voltage corresponds to a first voltage or a second voltage.

FIG. 20 is a flowchart of a method of notifying a user of a damaged state when a three-phase motor or a motor driver circuit is damaged, according to an embodiment.

According to an embodiment, operations 2010 and 2020 below may be performed by a diagnostic module of a wearable device (e.g., the wearable device 100 of FIG. 1). For example, operations 2010 and 2020 may be performed by a processor (e.g., the processor 512 of FIG. 5A) of the diagnostic module.

According to an embodiment, operations 2010 and 2020 may be performed after operation 1120 described above with reference to FIG. 11A is performed. For example, operations 2010 and 2020 may be performed when it is determined that at least one of the coils (e.g., the U-phase coil 902, the V-phase coil 904, and the W-phase coil 906) of the three-phase motor (e.g., the motor 534 of FIG. 5A or the three-phase motor 900 of FIG. 9) is abnormal. Operation 2010 and operation 2020 may be performed in parallel and independently.

According to an embodiment, operations 2010 and 2020 may be performed after operation 1320 described above with reference to FIG. 13 is performed. For example, operations 2010 and 2020 may be performed when it is determined that at least one of the bottom transistors of the motor driver circuit (e.g., the motor driver circuit 532 of FIG. 5A or the motor driver circuit 910 of FIG. 9) is abnormal.

In operation 2010, the processor of the diagnostic module may transmit information about the damage state of the three-phase motor or the motor driver circuit to a server (e.g., the server 230 of FIG. 2). For example, the processor of the diagnostic module may transmit information about the damage state of the three-phase motor or the motor driver circuit to the server through a communication module (e.g., the communication module 516 of FIG. 5A).

According to an embodiment, the processor of the diagnostic module may transmit a unique number of a wearable device or user account information to the server, along with the information about the damage state of the three-phase motor or the motor driver circuit. For example, the server may search for a countermeasure method for the damage based on the damage information received from the wearable device and transmit the countermeasure method to the wearable device or an electronic device (e.g., the electronic device 210 of FIG. 2) of the user. For example, the countermeasure method to the damage may be guidance on the location of a service center that the user may use.

In operation 2020, the processor of the diagnostic module may inform the user of the damage state of the three-phase motor or the motor driver circuit. For example, the processor of the diagnostic module may inform the user of the damage state of the three-phase motor or the motor driver circuit through a user interface, such as a lighting unit (e.g., the lighting unit 85 of FIG. 1). For example, the processor of the diagnostic module may transmit information about the damage state of the three-phase motor or the motor driver circuit to the electronic device of the user through the communication module.

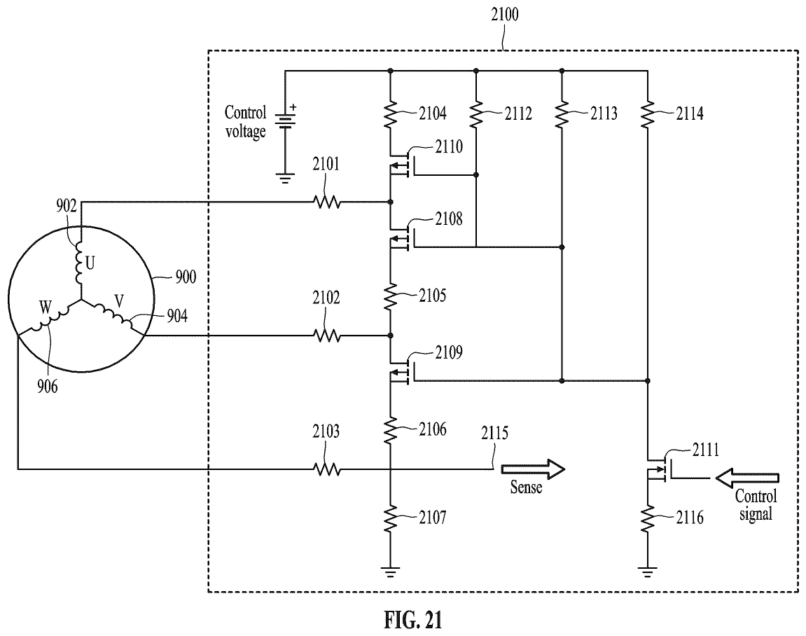

FIG. 21 illustrates a diagnostic circuit having a structure different from that of the diagnostic circuit shown in FIG. 9, according to an embodiment.

According to an embodiment, a diagnostic circuit 2100 (e.g., the diagnostic circuit 560 of FIG. 5A) may be electrically connected to the three-phase motor 900 (e.g., the motor 534 of FIG. 5A) described above with reference to FIG. 9. For example, the diagnostic circuit 2100 may be connected to each of the U-phase coil 902, the V-phase coil 904, and the W-phase coil 906 of the three-phase motor 900.

According to an embodiment, the diagnostic circuit 2100 may be electrically connected to the motor driver circuit 910 described above with reference to FIG. 9 through a terminal of the U-phase coil 902, a terminal of the V-phase coil 904, and a terminal of the W-phase coil 906 of the three-phase motor 900.

Hereinafter, the U-phase coil 902 may be referred to as a first coil, the V-phase coil 904 may be referred to as a second coil, and the W-phase coil 906 may be referred to as a third coil.

The diagnostic circuit 2100 may include a first terminal resistor 2101 connected to a first terminal connected to the first coil of the three-phase motor, a second terminal resistor 2102 connected to a second terminal connected to the second coil of the three-phase motor, and a third terminal resistor 2103 connected to a third terminal connected to the third coil of the three-phase motor. The third terminal resistor 2103 may be connected to an output terminal 2115.

The diagnostic circuit 2100 may include a first resistor 2104, a first gate resistor 2112, a second gate resistor 2113, and a third gate resistor 2114 each connected to a power source. For example, the power source may be a system power source or a battery.

The diagnostic circuit 2100 may include a first transistor 2108 having a gate terminal connected to the second gate resistor 2113, a drain terminal connected to the first terminal resistor 2101, and a source terminal connected to a second resistor 2105. The first transistor 2108 may be a p-FET.

The diagnostic circuit 2100 may include the second resistor 2105 positioned between the source terminal of the first transistor 2108 and the second terminal resistor 2102.

The diagnostic circuit 2100 may include a second transistor 2109 having a gate terminal connected to the third gate resistor 2114, a drain terminal connected to the second terminal resistor 2102, and a source terminal connected to a third resistor 2106. The second transistor 2109 may be a p-FET.

The diagnostic circuit 2100 may include the third resistor 2106 positioned between the source terminal of the second transistor 2109 and the third terminal resistor 2103.

The diagnostic circuit 2100 may include a fourth resistor 2107 having a first terminal connected to the third terminal resistor 2103 and the third resistor 2106, and a second terminal connected to the ground. The first terminal of the fourth resistor 2107 may be connected to the output terminal 2115.

The diagnostic circuit 2100 may include a third transistor 2110 having a gate terminal connected to the first gate resistor 2112, a drain terminal connected to the first resistor 2104, and a source terminal connected to the first terminal resistor 2101. The third transistor 2110 may be a p-FET.

The diagnostic circuit 2100 may include a fourth transistor 2111 having a drain terminal connected to the first gate resistor 2112, the second gate resistor 2113, the third gate resistor 2114, the gate terminal of the first transistor 2108, the gate terminal of the second transistor 2109, and the gate terminal of the third transistor 2110, a source terminal connected to a pull-down resistor 2116, and a gate terminal connected to the input terminal. The fourth transistor 2111 may be an n-FET.

The diagnostic circuit 2100 may include the pull-down resistor 2116 positioned between at least the source terminal of the fourth transistor 2111 and the ground.

According to an embodiment, a method of determining a state of a three-phase motor 534; 900 may include applying 810 a control voltage to an input terminal 1011 of a diagnostic circuit 560; 1000; 2100 electrically connected, directly or indirectly, to terminals of the three-phase motor 534; 900, measuring 820 a diagnostic voltage appearing at an output terminal 1012 of the diagnostic circuit 560; 1000; 2100, and determining 830 whether coils 902; 904; 906 of the three-phase motor 534; 900 are normal based on the diagnostic voltage.

According to an embodiment, the diagnostic circuit 560; 1000; 2100 may include a first terminal resistor 1001 connected, directly or indirectly, to a first terminal connected, directly or indirectly, to a first coil 902 of the three-phase motor 534; 900.

According to an embodiment, the diagnostic circuit 560; 1000; 2100 may include a second terminal resistor 1002 connected, directly or indirectly, to a second terminal connected, directly or indirectly, to a second coil 904 of the three-phase motor 534; 900.

According to an embodiment, the diagnostic circuit 560; 1000; 2100 may include a third terminal resistor 1003 connected, directly or indirectly, to a third terminal connected, directly or indirectly, to a third coil 906 of the three-phase motor (534; 900), and connected, directly or indirectly, to the output terminal 1012.

According to an embodiment, the diagnostic circuit 560; 1000; 2100 may include a first resistor 1004 positioned between at least the first terminal resistor 1003 and the input terminal 1011.

According to an embodiment, the diagnostic circuit 560; 1000; 2100 may include a first transistor 1008 having a drain terminal connected, directly or indirectly, to the first terminal resistor 1001 and the first resistor 1004, a source terminal connected, directly or indirectly, to the second resistor 1005, and a gate terminal connected, directly or indirectly, to the input terminal 1011.

According to an embodiment, the diagnostic circuit 560; 1000; 2100 may include a second resistor 1005 positioned between at least the source terminal of the first transistor 1008 and the second terminal resistor 1002.

According to an embodiment, the diagnostic circuit 560; 1000; 2100 may include a second transistor 1009 having a drain terminal connected, directly or indirectly, to the second terminal resistor 1002 and the second resistor 1005, a source terminal connected, directly or indirectly, to a third resistor 1006, and a gate terminal connected, directly or indirectly, to the input terminal 1011.

According to an embodiment, the diagnostic circuit 560; 1000; 2100 may include the third resistor 1006 positioned between at least the third terminal resistor 1003 and the source terminal of the second transistor 1009.

According to an embodiment, the diagnostic circuit 560; 1000; 2100 may include a fourth resistor 1007 having a first terminal connected, directly or indirectly, to the third terminal resistor 1003 and the third resistor 1006, and a second terminal connected, directly or indirectly, to a ground.

According to an embodiment, the diagnostic circuit 560; 1000; 2100 may include a pull-down resistor 1010 having a first terminal connected, directly or indirectly, to the input terminal 1011, the gate terminal of the first transistor 1008, and the gate terminal of the second transistor 1009, and a second terminal connected, directly or indirectly, to the ground.

According to an embodiment, each of the first transistor 1008 and the second transistor 1009 may be an n-FET.

According to an embodiment, the diagnostic circuit 560; 1000; 2100 may include a first terminal resistor 2101 connected, directly or indirectly, to a first terminal connected, directly or indirectly, to a first coil 902 of the three-phase motor 534; 900.

According to an embodiment, the diagnostic circuit 560; 1000; 2100 may include a second terminal resistor 2102 connected, directly or indirectly, to a second terminal connected, directly or indirectly, to a second coil 904 of the three-phase motor 534; 900.

According to an embodiment, the diagnostic circuit 560; 1000; 2100 may include a third terminal resistor 2103 connected, directly or indirectly, to a third terminal connected, directly or indirectly, to a third coil 906 of the three-phase motor 534; 900 and connected, directly or indirectly, to the output terminal.

According to an embodiment, the diagnostic circuit 560; 1000; 2100 may include a first resistor 2104, a first gate resistor 2112, a second gate resistor 2113, and a third gate resistor 2114 each connected, directly or indirectly, to a power supply.

According to an embodiment, the diagnostic circuit 560; 1000; 2100 may include a first transistor 2108 having a gate terminal connected, directly or indirectly, to the second gate resistor 2113, a drain terminal connected, directly or indirectly, to the first terminal resistor 2101, and a source terminal connected, directly or indirectly, to a second resistor 2105.

According to an embodiment, the diagnostic circuit 560; 1000; 2100 may include the second resistor 2105 positioned between at least the source terminal of the first transistor 2108 and the second terminal resistor 2102.

According to an embodiment, the diagnostic circuit 560; 1000; 2100 may include a second transistor 2109 having a gate terminal connected, directly or indirectly, to the third gate resistor 2114, a drain terminal connected, directly or indirectly, to the second terminal resistor 2102, and a source terminal connected, directly or indirectly, to a third resistor 2106.

According to an embodiment, the diagnostic circuit 560; 1000; 2100 may include the third resistor 2106 positioned between at least the source terminal of the second transistor 2109 and the third terminal resistor 2103.

According to an embodiment, the diagnostic circuit 560; 1000; 2100 may include a fourth resistor 2107 having a first terminal connected, directly or indirectly, to the third terminal resistor 2103 and the third resistor 2106, and a second terminal connected, directly or indirectly, to a ground.

According to an embodiment, the diagnostic circuit 560; 1000; 2100 may include a third transistor 2110 having a gate terminal connected, directly or indirectly, to the first gate resistor 2112, a drain terminal connected, directly or indirectly, to the first resistor 2104, and a source terminal connected, directly or indirectly, to the first terminal resistor 2101. “Connected” as used herein covers both direct and indirect connections.

Each embodiment herein may be used in combination with any other embodiment(s) described herein.

According to an embodiment, the diagnostic circuit 560; 1000; 2100 may include a fourth transistor 2111 having a drain terminal connected, directly or indirectly, to the first gate resistor 2112, the second gate resistor 2113, the third gate resistor 2114, the gate terminal of the first transistor 2108, the gate terminal of the second transistor 2109, and the gate terminal of the third transistor 2110, a source terminal connected, directly or indirectly, to a pull-down resistor 2116, and a gate terminal connected, directly or indirectly, to the input terminal.

According to an embodiment, the diagnostic circuit 560; 1000; 2100 may include the pull-down resistor 2116 positioned between at least the source terminal of the fourth transistor 2111 and the ground.

According to an embodiment, each of the first transistor 2108, the second transistor 2109, and the third transistor 2110 may be a p-FET, and the fourth transistor 2111 may be an n-FET.

According to an embodiment, the determining 830 of whether coils 902; 904; 906 of the three-phase motor 534; 900 are normal based on the diagnostic voltage may include determining 1110 whether the diagnostic voltage corresponds to a first voltage, and determining 1120 that a target coil among the coils 902; 904; 906 corresponding to the first voltage is damaged, when the diagnostic voltage corresponds to the first voltage.

According to an embodiment, the determining 830 of whether coils 902; 904; 906 of the three-phase motor 534; 900 are normal based on the diagnostic voltage may include determining 1310 whether the diagnostic voltage corresponds to a second voltage, and determining 1320 that at least one of one or more transistors 915; 916; 917 of a motor driver circuit 910 connected, directly or indirectly, to the three-phase motor 534; 900 is damaged, when the diagnostic voltage corresponds to the second voltage.

According to an embodiment, the method of determining a state of the three-phase motor 534; 900 may further include terminating 1510 applying the control voltage and applying a driving voltage to a motor driver circuit 910 connected, directly or indirectly, to the three-phase motor 534; 900, when it is determined that the coils 902; 904; 906 of the three-phase motor 534; 900 are normal, measuring 1520 an additional diagnostic voltage appearing at the output terminal 1012 of the diagnostic circuit 560; 1000; 2100, determining 1530 whether the additional diagnostic voltage corresponds to a third voltage, and determining 1540 that at least one of one or more transistors 912; 913; 914 of the motor driver circuit 910 is damaged, when the additional diagnostic voltage corresponds to the third voltage.

According to an embodiment, the method of determining a state of the three-phase motor 534; 900 may further include terminating 1710 applying the control voltage and applying a driving voltage to a motor driver circuit 910 connected, directly or indirectly, to the three-phase motor 534; 900, when it is determined that the coils 902; 904; 906 of the three-phase motor 534; 900 are normal, measuring 1720 an operating voltage appearing at the output terminal 1012 of the diagnostic circuit 560; 1000; 2100 while the three-phase motor 534; 900 is controlled by the motor driver circuit 910 based on PWM, and terminating 1730 applying the driving voltage when the operating voltage is abnormal.

According to an embodiment, a diagnostic module for determining whether coils 902; 904; 906 of a three-phase motor 534; 900 are normal may include a processor 512, and a diagnostic circuit 560; 1000; 2100, wherein the processor 512 may perform applying 810 a control voltage to an input terminal 1011 of the diagnostic circuit 560; 1000; 2100 electrically connected, directly or indirectly, to terminals of the three-phase motor 534; 900, measuring 820 a diagnostic voltage appearing at an output terminal 1012 of the diagnostic circuit 560; 1000; 2100, and determining 830 whether coils 902; 904; 906 of the three-phase motor 534; 900 are normal based on the diagnostic voltage.

According to an embodiment, the processor 512 may further perform determining 1110 whether the diagnostic voltage corresponds to a first voltage, and determining 1120 that a target coil among the coils 902; 904; 906 corresponding to the first voltage is damaged, when the diagnostic voltage corresponds to the first voltage.

According to an embodiment, the processor 512 may further perform determining 1310 whether the diagnostic voltage corresponds to a second voltage, and determining 1320 that at least one of one or more transistors 915; 916; 917 of a motor driver circuit 910 connected, directly or indirectly, to the three-phase motor 534; 900 is damaged, when the diagnostic voltage corresponds to the second voltage.

According to an embodiment, the processor 512 may further perform terminating 1510 applying the control voltage and applying a driving voltage to a motor driver circuit 910 connected, directly or indirectly, to the three-phase motor 534; 900, when it is determined that the coils 902; 904; 906 of the three-phase motor 534; 900 are normal, measuring 1520 an additional diagnostic voltage appearing at the output terminal 1012 of the diagnostic circuit 560; 1000; 2100, determining 1530 whether the additional diagnostic voltage corresponds to a third voltage, and determining 1540 that at least one of one or more transistors 912; 913; 914 of the motor driver circuit 910 is damaged, when the additional diagnostic voltage corresponds to the third voltage.

According to an embodiment, the processor 512 may further perform terminating 1710 applying the control voltage and applying a driving voltage to a motor driver circuit 910 connected, directly or indirectly, to the three-phase motor 534; 900, when it is determined that the coils 902; 904; 906 of the three-phase motor 534; 900 are normal, measuring 1720 an operating voltage appearing at the output terminal 1012 of the diagnostic circuit 560; 1000; 2100 while the three-phase motor 534; 900 is controlled by the motor driver circuit 910 based on PWM, and terminating 1730 applying the driving voltage when the operating voltage is abnormal.

According to an embodiment, a method of determining a state of a three-phase motor 534; 900 may include measuring 1720 an operating voltage appearing at an output terminal 1012 of a diagnostic circuit 560; 1000; 2100 electrically connected, directly or indirectly, to terminals of the three-phase motor 534; 900 while the three-phase motor 534; 900 is controlled by a motor driver circuit 910 based on PWM, terminating 1730 applying a driving voltage to the three-phase motor 534; 900 when the operating voltage is abnormal, applying 810 a control voltage to an input terminal 1011 of the diagnostic circuit 560; 1000; 2100, measuring 820 a diagnostic voltage appearing at the output terminal 1012 of the diagnostic circuit 560; 1000; 2100, and determining 830 whether coils 902; 904; 906 of the three-phase motor 534; 900 are normal based on the diagnostic voltage. “Based on” as used herein covers based at least on.

The embodiments described herein may be implemented using a hardware component, a software component and/or a combination thereof. A processing device may be implemented using one or more general-purpose or special-purpose computers, such as, for example, a processor, a controller and an arithmetic logic unit (ALU), a DSP, a microcomputer, a field-programmable gate array (FPGA), a programmable logic unit (PLU), a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciate that a processing device may include multiple processing elements and multiple types of processing elements. For example, the processing device may include a plurality of processors, or a single processor and a single controller. In addition, different processing configurations are possible, such as parallel processors.

Each “processor” herein includes processing circuitry, and/or may include multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The software may include a computer program, a piece of code, an instruction, or some combination thereof, to independently or uniformly instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network-coupled computer systems so that the software is stored and executed in a distributed fashion. The software and data may be stored by one or more non-transitory computer-readable recording mediums.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher-level code that may be executed by the computer using an interpreter.

The above-described devices may be configured to act as one or more software modules in order to perform the operations of the above-described examples, or vice versa.

As described above, although the embodiments have been described with reference to the limited drawings, a person skilled in the art may apply various technical modifications and variations based thereon. For example, suitable results may be achieved if the described techniques are performed in a different order and/or if components in a described system, architecture, device, or circuit are combined in a different manner and/or replaced or supplemented by other components or their equivalents.

While the disclosure has been illustrated and described with reference to various embodiments, it will be understood that the various embodiments are intended to be illustrative, not limiting. It will further be understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

Accordingly, other implementations are within the scope of the following claims.

What is claimed is:

1. A method of determining a state of a three-phase motor, the method comprising:
applying a control voltage to an input terminal of a diagnostic circuit electrically connected to terminals of the three-phase motor;
measuring a diagnostic voltage appearing at an output terminal of the diagnostic circuit; and
determining whether coils of the three-phase motor are normal based on the diagnostic voltage.

2. The method of claim 1, wherein the diagnostic circuit comprises:
a first terminal resistor connected to a first terminal connected to a first coil of the three-phase motor;
a second terminal resistor connected to a second terminal connected to a second coil of the three-phase motor;
a third terminal resistor connected to a third terminal connected to a third coil of the three-phase motor, and connected to the output terminal;
a first resistor positioned between the first terminal resistor and the input terminal;
a first transistor having a drain terminal connected to the first terminal resistor and the first resistor, a source terminal connected to the second resistor, and a gate terminal connected to the input terminal;
a second resistor positioned between at least the source terminal of the first transistor and the second terminal resistor;
a second transistor having a drain terminal connected to the second terminal resistor and the second resistor, a source terminal connected to a third resistor, and a gate terminal connected to the input terminal;
the third resistor positioned between at least the third terminal resistor and the source terminal of the second transistor;
a fourth resistor having a first terminal connected to the third terminal resistor and the third resistor, and a second terminal connected to a ground; and
a pull-down resistor having a first terminal connected to the input terminal, the gate terminal of the first transistor, and the gate terminal of the second transistor, and a second terminal connected to the ground.

3. The method of claim 2, wherein each of the first transistor and the second transistor is an n-field-effect transistor (n-FET).

4. The method of claim 1, wherein the diagnostic circuit comprises:
a first terminal resistor connected to a first terminal connected to a first coil of the three-phase motor;
a second terminal resistor connected to a second terminal connected to a second coil of the three-phase motor;
a third terminal resistor connected to a third terminal connected to a third coil of the three-phase motor, and connected to the output terminal;
a first resistor, a first gate resistor, a second gate resistor, and a third gate resistor each connected to a power supply;
a first transistor having a gate terminal connected to the second gate resistor, a drain terminal connected to the first terminal resistor, and a source terminal connected to a second resistor;
the second resistor positioned between at least the source terminal of the first transistor and the second terminal resistor;
a second transistor having a gate terminal connected to the third gate resistor, a drain terminal connected to the second terminal resistor, and a source terminal connected to a third resistor;
the third resistor positioned between at least the source terminal of the second transistor and the third terminal resistor;
a fourth resistor having a first terminal connected to the third terminal resistor and the third resistor, and a second terminal connected to a ground;
a third transistor having a gate terminal connected to the first gate resistor, a drain terminal connected to the first resistor, and a source terminal connected to the first terminal resistor;
a fourth transistor having a drain terminal connected to the first gate resistor, the second gate resistor, the third gate resistor, the gate terminal of the first transistor, the gate terminal of the second transistor, and the gate terminal of the third transistor, a source terminal connected to a pull-down resistor, and a gate terminal connected to the input terminal; and
the pull-down resistor positioned between at least the source terminal of the fourth transistor and the ground.

5. The method of claim 4, wherein
each of the first transistor, the second transistor, and the third transistor is a p-field-effect transistor (p-FET), and
the fourth transistor is an n-FET.

6. The method of claim 1, wherein the determining of whether coils of the three-phase motor are normal based on the diagnostic voltage comprises:
determining whether the diagnostic voltage corresponds to a first voltage; and
determining that a target coil among the coils corresponding to the first voltage is damaged, when the diagnostic voltage corresponds to the first voltage.

7. The method of claim 1, wherein the determining of whether coils of the three-phase motor are normal based on the diagnostic voltage comprises:
determining whether the diagnostic voltage corresponds to a second voltage; and
determining that at least one of one or more transistors of a motor driver circuit connected to the three-phase motor is damaged, when the diagnostic voltage corresponds to the second voltage.

8. The method of claim 1, further comprising:
terminating applying the control voltage and applying a driving voltage to a motor driver circuit connected to the three-phase motor, when it is determined that the coils of the three-phase motor are normal;
measuring an additional diagnostic voltage appearing at the output terminal of the diagnostic circuit;
determining whether the additional diagnostic voltage corresponds to a third voltage; and
determining that at least one of one or more transistors of the motor driver circuit is damaged, when the additional diagnostic voltage corresponds to the third voltage.

9. The method of claim 1, further comprising:
terminating applying the control voltage and applying a driving voltage to a motor driver circuit connected to the three-phase motor, when it is determined that the coils of the three-phase motor are normal;
measuring an operating voltage appearing at the output terminal of the diagnostic circuit while the three-phase motor is controlled by the motor driver circuit based on pulse width modulation (PWM); and
terminating applying the driving voltage when the operating voltage is abnormal.

10. A non-transitory computer-readable storage medium storing instructions that, when executed by a processor, cause the processor to perform the method of claim 1.

11. A diagnostic module for determining whether coils of a three-phase motor are normal, the diagnostic module comprising:
a diagnostic circuit; and
at least one processor, comprising processing circuitry, individually and/or collectively configured to perform:
applying a control voltage to an input terminal of the diagnostic circuit electrically connected to terminals of the three-phase motor;
measuring a diagnostic voltage appearing at an output terminal of the diagnostic circuit; and
determining whether coils of the three-phase motor are normal based on the diagnostic voltage.

12. The diagnostic module of claim 11, wherein the diagnostic circuit comprises:
a first terminal resistor connected to a first terminal connected to a first coil of the three-phase motor;
a second terminal resistor connected to a second terminal connected to a second coil of the three-phase motor;
a third terminal resistor connected to a third terminal connected to a third coil of the three-phase motor, and connected to the output terminal;
a first resistor positioned between the first terminal resistor and the input terminal;
a first transistor having a drain terminal connected to the first terminal resistor and the first resistor, a source terminal connected to the second resistor, and a gate terminal connected to the input terminal;
a second resistor positioned between at least the source terminal of the first transistor and the second terminal resistor;
a second transistor having a drain terminal connected to the second terminal resistor and the second resistor, a source terminal connected to a third resistor, and a gate terminal connected to the input terminal;
the third resistor positioned between at least the third terminal resistor and the source terminal of the second transistor;
a fourth resistor having a first terminal connected to the third terminal resistor and the third resistor, and a second terminal connected to a ground; and
a pull-down resistor having a first terminal connected to the input terminal, the gate terminal of the first transistor, and the gate terminal of the second transistor, and a second terminal connected to the ground.

13. The diagnostic module of claim 12, wherein each of the first transistor and the second transistor is an n-field-effect transistor (n-FET).

14. The diagnostic module of claim 11, wherein the diagnostic circuit comprises:
a first terminal resistor connected to a first terminal connected to a first coil of the three-phase motor;
a second terminal resistor connected to a second terminal connected to a second coil of the three-phase motor;
a third terminal resistor connected to a third terminal connected to a third coil of the three-phase motor, and connected to the output terminal;
a first resistor, a first gate resistor, a second gate resistor, and a third gate resistor each connected to a power supply;
a first transistor having a gate terminal connected to the second gate resistor, a drain terminal connected to the first terminal resistor, and a source terminal connected to a second resistor;
the second resistor positioned between at least the source terminal of the first transistor and the second terminal resistor;
a second transistor having a gate terminal connected to the third gate resistor, a drain terminal connected to the second terminal resistor, and a source terminal connected to a third resistor;
the third resistor positioned between at least the source terminal of the second transistor and the third terminal resistor;
a fourth resistor having a first terminal connected to the third terminal resistor and the third resistor, and a second terminal connected to a ground;
a third transistor having a gate terminal connected to the first gate resistor, a drain terminal connected to the first resistor, and a source terminal connected to the first terminal resistor;
a fourth transistor having a drain terminal connected to the first gate resistor, the second gate resistor, the third gate resistor, the gate terminal of the first transistor, the gate terminal of the second transistor, and the gate terminal of the third transistor, a source terminal connected to a pull-down resistor, and a gate terminal connected to the input terminal; and
the pull-down resistor positioned between the source terminal of the fourth transistor and the ground.

15. The diagnostic module of claim 14, wherein
each of the first transistor, the second transistor, and the third transistor is a p-field-effect transistor (p-FET), and
the fourth transistor is an n-FET.

16. The diagnostic module of claim 11, wherein the at least one processor is further configured to perform:
determining whether the diagnostic voltage corresponds to a first voltage; and
determining that a target coil among the coils corresponding to the first voltage is damaged, when the diagnostic voltage corresponds to the first voltage.

17. The diagnostic module of claim 11, wherein the at least one processor is further configured to perform:
determining whether the diagnostic voltage corresponds to a second voltage; and
determining that at least one of one or more transistors of a motor driver circuit connected to the three-phase motor is damaged, when the diagnostic voltage corresponds to the second voltage.

18. The diagnostic module of claim 11, wherein the at least one processor is further configured to perform:
terminating applying the control voltage and applying a driving voltage to a motor driver circuit connected to the three-phase motor, when it is determined that the coils of the three-phase motor are normal;
measuring an additional diagnostic voltage appearing at the output terminal of the diagnostic circuit;
determining whether the additional diagnostic voltage corresponds to a third voltage; and
determining that at least one of one or more transistors of the motor driver circuit is damaged, when the additional diagnostic voltage corresponds to the third voltage.

19. The diagnostic module of claim 11, wherein the at least one processor is further configured to perform:
terminating applying the control voltage and applying a driving voltage to a motor driver circuit connected to the three-phase motor, when it is determined that the coils of the three-phase motor are normal;
measuring an operating voltage appearing at the output terminal of the diagnostic circuit while the three-phase motor is controlled by the motor driver circuit based on pulse width modulation (PWM); and
terminating applying the driving voltage when the operating voltage is abnormal.

20. A method of determining a state of a three-phase motor, the method comprising:
measuring an operating voltage appearing at an output terminal of a diagnostic circuit electrically connected to terminals of the three-phase motor while the three-phase motor is controlled by a motor driver circuit based on pulse width modulation (PWM);
terminating applying a driving voltage to the three-phase motor when the operating voltage is abnormal;
applying a control voltage to an input terminal of the diagnostic circuit;
measuring a diagnostic voltage appearing at the output terminal of the diagnostic circuit; and
determining whether coils of the three-phase motor are normal based on the diagnostic voltage.
